(19) United States
(12) Patent Application Publication
(10) Pub. No.: US 2016/0042702 A1
(43) Pub. Date: Feb. 11, 2016

(54) DISPLAY PANEL, DISPLAY DEVICE, AND DRIVING METHOD OF DISPLAY DEVICE

(71) Applicant: Semiconductor Energy Laboratory Co., Ltd., Atsugi-shi (JP)

(72) Inventors: Yoshiharu HIRAKATA, Ebina (JP); Shunpei YAMAZAKI, Tokyo (JP)

(21) Appl. No.: 14/820,773

(22) Filed: Aug. 7, 2015

(30) Foreign Application Priority Data
Aug. 8, 2014 (JP) 2014-162359

(51) Int. Cl. G09G 3/36; G02F 1/135; G02F 1/1368; H01L 29/786; H01L 27/32; G02F 1/1334

(52) U.S. Cl. CPC G09G 3/36; H01L 27/3232; G02F 1/1334; H01L 27/3267; G02F 1/1368; H01L 27/322; H01L 29/7869; H01L 27/3269; G02F 1/135; G09G 2300/04; G09G 2330/021; G02F 2001/136222

(57) ABSTRACT

The display panel includes a first display element and a second display element. The first display element is capable of emitting light. The second display element is capable of transmit or disperse light. The second display element is overlapped with the first display element on a light-emitting side of the first display element. Each of the first display elements and the second display elements is arranged in a matrix in a display region.

### TECHNICAL FIELD

One embodiment of the present invention relates to a display panel, a display device, and a driving method of the display device.

Note that one embodiment of the present invention is not limited to the technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, an input/output device, a method for driving any of them, and a method for manufacturing any of them.

### BACKGROUND ART

A liquid-crystal display device including a liquid-crystal element and a light-emitting device including a light-emitting element are generally used as a display device used for a portable information terminal and the like. A portable information terminal is often used outside and should stand long-time use, and also should have high visibility of a display screen under various environments.

As a measure against the problems, a liquid crystal display device in which a polarizing plate and/or a backlight are/is not necessarily involved and image display is performed by utilizing scattered light with a liquid crystal such as a polymer-dispersed liquid crystal (PDLC) or a polymer network liquid crystal (PNLC) has been researched (see Non-Patent Document 1, for example). The use of the liquid crystal display device can provide high visibility equivalent to paper on which pictures or characters are drawn with low power consumption.

### REFERENCE

### Non-Patent Document

[Non-Patent Document 1] M. Minoura et al., SID 06 DIGEST, pp. 769-772

### DISCLOSURE OF INVENTION

One object of one embodiment of the present invention is to provide a display panel with low power consumption, a display panel that is highly convenient, a novel display panel, a novel display device, or a novel method for driving a display device.

Note that the descriptions of these objects do not disturb the existence of other objects. One embodiment of the present invention does not need to achieve all the objects. Other objects will be apparent from and can be derived from the description of the specification, the drawings, the claims, and the like.

### MEANS FOR SOLVING THE PROBLEMS

One embodiment of the present invention is a display panel including a first display element and a second display element. The first display element is capable of emitting light. The second display element is capable of transmit or disperse light. The second display element is overlapped with the first display element on a light-emitting side of the first display element. Each of the first display elements and the second display elements is arranged in a matrix in a display region.

The display panel includes a coloring layer. The second display element can be provided between the coloring layer and the first display element.

The display panel includes the first display element and the second display element between a first support and a second support. The second display element is capable of transmitting or dispersing light emitted from the first display element. The first display element and the second display element can be selectively used.

The first display element includes a layer containing a light-emitting organic compound. The second display element includes a layer containing a polymer-dispersed liquid crystal.

Another embodiment of the present invention is a display device including a display panel, a light sensor, and a driving device. The display panel includes a first display element and a second display element. The light sensor is capable of sensing illuminance of an use environment of the display panel. The driving device is capable of supplying an image signal to the first display element and a signal to the second display element to transmit light in the case where the illuminance sensed by the light sensor is less than a predetermined illuminance, and supply image data to the second display element in the case where the illuminance sensed by the light sensor is more than or equal to the predetermined illuminance.

Another embodiment of the present invention is a driving method of a display device including a first step of obtaining illuminance data, a second step of supplying an image signal to a first display element and a signal for making a second display element a light-transmitting state to the second display element, and a third step of turning the first display element off and supplying the image signal to the second display element. In the case where the illuminance data contains data of illuminance less than a predetermined illuminance in the first step, the second step starts; and in the case where the illuminance data contains data of illuminance more than or equal to the predetermined illuminance in the first step, the third step starts.

One embodiment of the present invention can provide a display panel with low power consumption, a display panel that is highly convenient, a novel display panel, a novel display device, or a novel method for driving a display device.

Note that the description of these effects does not disturb the existence of other effects. One embodiment of the present invention does not necessarily achieve all the objects listed above. Other effects will be apparent from and can be derived from the description of the specification, the drawings, the claims, and the like.

### BRIEF DESCRIPTION OF DRAWINGS

FIGS. 1A and 1B are schematic diagrams illustrating a structure of a display panel of one embodiment.

FIGS. 2A to 2C are schematic diagrams illustrating structures of a display panel of one embodiment.

FIGS. 3A to 3C are schematic diagrams illustrating display modes of a display panel of one embodiment.

FIGS. 4A and 4B are cross-sectional views illustrating a display panel of one embodiment.

FIG. 5 is a block diagram of a display device of one embodiment.

FIG. 6 is a flow chart showing operation of a display device of one embodiment.

FIGS. 7A to 7C are projection views illustrating the structure of a data processing device of one embodiment.

FIGS. 8A to 8D are Cs-corrected high-resolution TEM images of a cross section of a CAAC-OS and a cross-sectional schematic view of the CAAC-OS.

FIGS. 9A to 9D are Cs-corrected high-resolution TEM images of a plane of a CAAC-OS.

FIGS. 10A to 10C show structural analysis of a CAAC-OS and a single crystal oxide semiconductor by XRD.

FIGS. 11A and 11B show electron diffraction patterns of a CAAC-OS.

FIG. 12 shows a change in crystal part of an In—Ga—Zn oxide induced by electron irradiation.

FIGS. 13A and 13B are schematic diagrams illustrating deposition models of a CAAC-OS layer and an nc-OS layer.

FIGS. 14A to 14C illustrate an InGaZnO₄ crystal and a pellet.

FIGS. 15A to 15D are schematic diagrams illustrating a deposition model of a CAAC-OS.

FIGS. 16A to 16D are diagrams illustrating electronic devices.

### BEST MODE FOR CARRYING OUT THE INVENTION

Embodiments will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the content of the embodiments below. Note that in the structures of the invention described below, the same portions or portions having similar functions are denoted by the same reference numerals in different drawings, and description of such portions is not repeated.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

In this specification, a layer between a pair of electrodes of an electroluminescent element is referred to as an EL layer. An organic electroluminescent element also includes a light-emitting layer containing a light-emitting organic compound. Hence, a light-emitting layer between a pair of electrodes is one mode of the EL layer.

The display panel includes the following in its category: a module to which a connector such as a flexible printed circuit (FPC) or a tape carrier package (TCP) is attached; a module having a TCP provided with a printed wiring board at the end thereof; and a substrate over which an integrated circuit (IC) is mounted by a chip on glass (COG) method and a display element is formed.

In this specification, one of a first electrode and a second electrode of a transistor refers to a source electrode and the other refers to a drain electrode.

### Embodiment 1

A display panel of one embodiment of the present invention includes a first display element and a second display element which are bonded with an adhesive agent.

The display mode is changed depending on environments owing to the combination of the first and second display elements. This provides a novel display panel with low power consumption and enhanced convenience, a manufacturing method of the display panel, or a novel display device provided with the display panel.

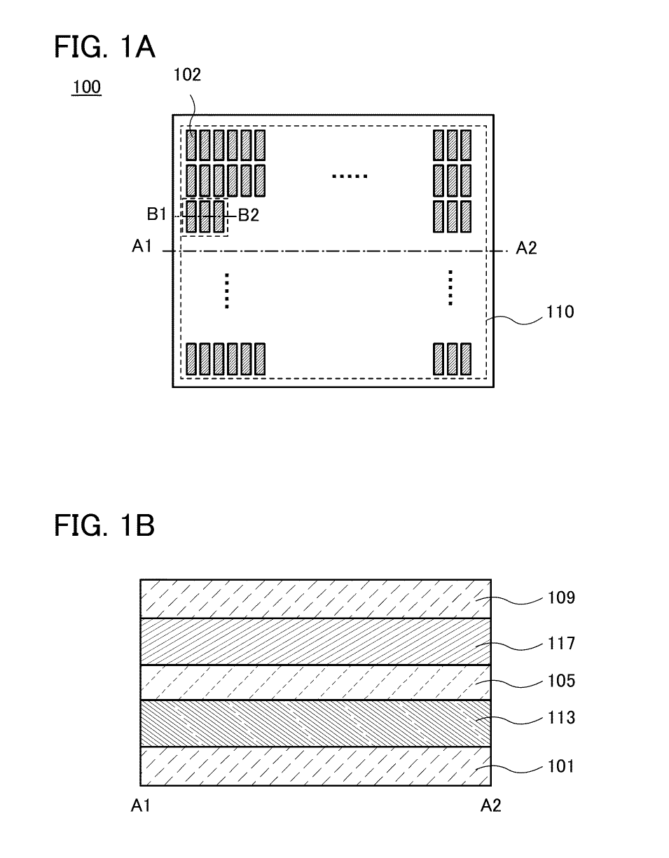

A structure of a display panel of one embodiment of the present invention will be described with reference to FIGS. 1A and 1B. FIGS. 1A and 1B illustrate the structure of a display panel 100 of one embodiment of the present invention.

FIG. 1A is a top view of the display panel 100 of one embodiment of the present invention. FIG. 1B is a cross-sectional view of the display panel 100 taken along cut line A1-A2 in FIG. 1A.

The display panel 100 of one embodiment of the present invention includes element layers 113 and 117 between substrates 101 and 109, and an adhesive layer 105 between the element layers 113 and 117.

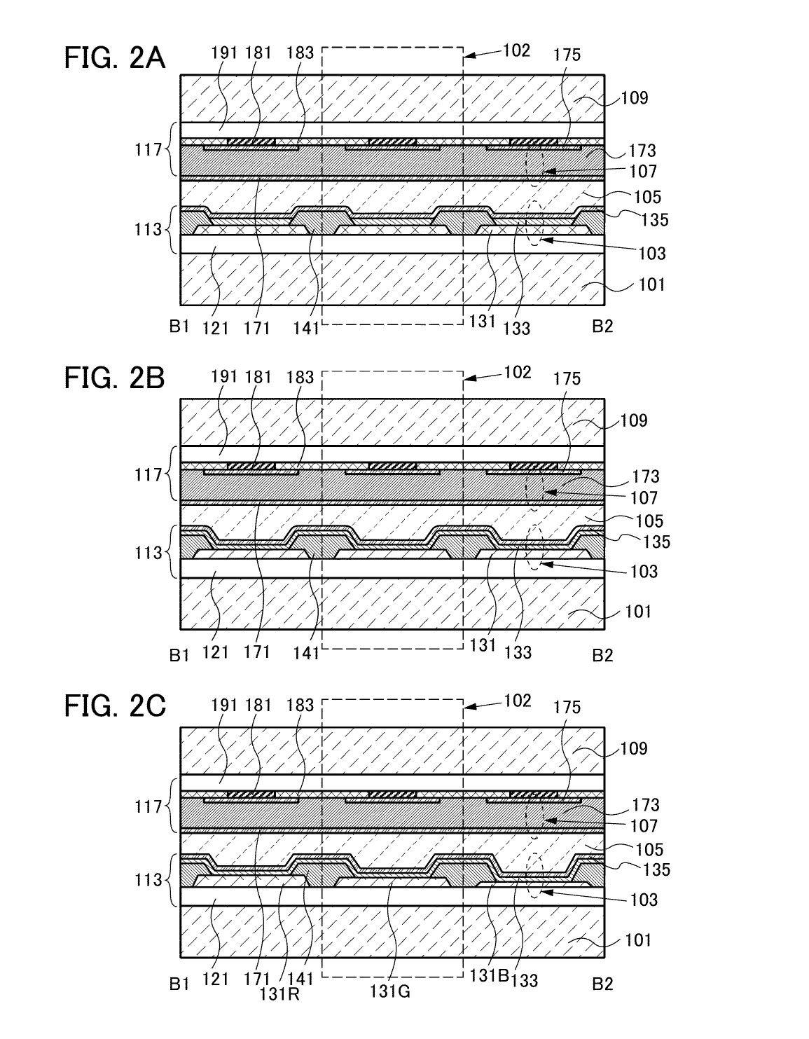

The element layer 113 includes a display element 103 and a transistor or the like for operating the display element 103, and the element layer 117 includes a display element 107 and a transistor or the like for operating the display element 107, as shown in FIG. 2A and the like.

A region where the display element 103 is overlapped with the display element 107 is included in an element region 102. The element regions 102 are arranged in matrix to form a display region 110.

### <Display Elements 103 and 107>

FIGS. 2A to 2C are cross-sectional views of the display panel 100 taken along cut line B1-B2 in FIG. 1A. The structures of the display elements 103 in FIGS. 2A to 2C are different from each other: an organic EL element formed by a separate coloring method is used as the display element 103 in FIG. 2A, an organic EL element emitting white light is used as the display element 103 in FIG. 2B, and an organic EL element having a microcavity structure is used as the display element 103 in FIG. 2C.

### <Element Layer 113>

The element layer 113 includes a transistor layer 121 over the substrate 101, a lower electrode 131 over the transistor layer 121, an insulating film 141 covering an end of the lower electrode 131, an EL layer 133 over the lower electrode 131 and in contact with the insulating film 141, and an upper electrode 135 in contact with the EL layer 133. Note that the transistor layer 121 may include an element, such as a resistor or a capacitor, other than the transistor for driving the display elements 103 and 107. The lower electrode 131 can reflect visible light. The upper electrode 135 can transmit visible light.

### <Element Layer 117>

The element layer 117 includes a transistor layer 191 overlapping with the substrate 109, a light-blocking layer 183 and a coloring layer 181 overlapping with the transistor layer 191, an electrode layer 175 having a light-transmitting property and overlapping with the light-blocking layer 183 and the coloring layer 181, a polymer-dispersed liquid crystal layer 173 overlapping with the electrode layer 175, and an electrode layer 171 having a light-transmitting property and overlapping with the polymer-dispersed liquid crystal layer 173.

The element region 102 corresponds to a region surrounded by a dashed frame in the figures and includes a region where the display element 103 overlaps with the display element 107. The coloring layer 181 overlaps the display elements 103 and 107.

Individual components included in the display panel 100 will be described below. Note that these units cannot be clearly distinguished and one unit also serves as another unit or include part of another unit in some cases.

### <Substrate 101>

There is no particular limitation on the substrate 101 as long as it has heat resistance high enough to withstand a manufacturing process and a thickness and a size which can be used in a manufacturing apparatus.

For the substrate 101, an organic material, an inorganic material, a composite material of an organic material and an inorganic material, or the like can be used. Examples of the inorganic material include glass, a ceramic, or a metal.

Specifically, non-alkali glass, soda-lime glass, potash glass, crystal glass, or the like can be used for the substrate 101. An inorganic oxide film, an inorganic nitride film, an inorganic oxynitride film, or the like can be used for the substrate 101. Silicon oxide, silicon nitride, silicon oxynitride, alumina, stainless steel, aluminum, or the like can be used for the substrate 101.

An organic material such as a resin, a resin film, or plastic can be used for the substrate 101. Specifically, a resin film or resin plate of polyester, polyolefin, polyamide, polyimide, polycarbonate, an acrylic resin, or the like can be used.

A composite material such as a resin film to which a metal plate, a thin glass plate, or a film of an inorganic material is attached; a composite material formed by dispersing a fibrous or particulate metal, glass, inorganic material, or the like into a resin film; and a composite material formed by dispersing a fibrous or particulate resin, organic material, or the like into an inorganic material.

Furthermore, a single-layer material or a stacked-layer material in which a plurality of layers are stacked; a stacked-layer material in which a base, an insulating film that prevents diffusion of impurities contained in the base, and the like are stacked can be used for the substrate 101. Specifically, a stacked-layer material in which glass and one or a plurality of films that prevent diffusion of impurities contained in the glass and that are selected from a silicon oxide layer, a silicon nitride layer, a silicon oxynitride layer, and the like are stacked can be used for the substrate 101. A stacked-layer material in which a resin and a film for preventing diffusion of impurities that penetrate the resin, such as a silicon oxide film, a silicon nitride film, and a silicon oxynitride film are stacked can be used for the substrate 101.

The above-described substrate that can be used as the substrate 101 can be used as the substrate 109 as well.

### <Transistor>

Various transistors can be used as transistors included in the transistor layers 121 and 191.

For example, a transistor in which a Group 14 element, a compound semiconductor, an oxide semiconductor, or the like is used for the semiconductor layer can be used. Specifically, a semiconductor containing silicon, a semiconductor containing gallium arsenide, an oxide semiconductor containing indium, or the like can be used.

For the semiconductor layer of the transistor, single crystal silicon, polysilicon, or amorphous silicon can be used.

A bottom-gate transistor, a top-gate transistor, or the like can be used.

The use of a transistor with extremely small off-state leakage current as a transistor connected to the display element 103 and a transistor connected to the display element 107 can extend time for holding image signals. For example, images can be held even when the frequency of writing image signals is more than or equal to 11.6 μHz (once a day) and less than 0.1 Hz (0.1 times a second), preferably more than or equal to 0.28 mHz (once an hour) and less than 1 Hz (once a second). The reduction in the frequency of writing image signals can reduce power consumption of the display panel 100. Needless to say, the frequency of writing image signals can be more than or equal to 30 Hz (30 times a second), preferably more than or equal to 60 Hz (60 times a second) and less than 960 Hz (960 times a second).

A transistor in which an oxide semiconductor is used for a semiconductor layer can be used as the transistor with extremely small off-state leakage current. Specifically, for the semiconductor layer, an oxide semiconductor containing at least indium (In), zinc (Zn), and M (M is a metal such as Al, Ga, Ge, Y, Zr, Sn, La, Ce, or Hf), which is represented by an In-M-Zn oxide, can be preferably used. It is preferable to contain both In and Zn.

In the case where the voltage between a source and a drain is set to about 0.1 V, 5 V, or 10 V, for example, the off-state current standardized on the channel width of the transistor in which an oxide semiconductor is used for the semiconductor layer can be as low as several yoctoamperes per micrometer to several zeptoamperes per micrometer.

As an oxide semiconductor included in an oxide semiconductor film, any of the following can be used, for example: an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, an In—Hf—Al—Zn-based oxide, and an In—Ga-based oxide.

Note that here, for example, an “In—Ga—Zn-based oxide” means an oxide containing In, Ga, and Zn as its main components and there is no limitation on the ratio of In:Ga:Zn. The In—Ga—Zn-based oxide may contain another metal element in addition to In, Ga, and Zn.

### <Display Element 103>

A light-emitting element can be used as the display element 103. As the light-emitting element, a self-luminous element can be used, and an element whose luminance is controlled by current or voltage is included in the category of the light-emitting element. For example, a light-emitting diode (LED), an organic EL element, an inorganic EL element, or the like can be used. For example, an organic element which includes a lower electrode, an upper electrode, and a layer (also referred to as an EL layer) containing a light-emitting organic compound between the lower electrode and the upper electrode can be used as the display element 103.

The light-emitting element may be a top emission, bottom emission, or dual emission light-emitting element. A conductive film that transmits visible light is used as the electrode through which light is extracted. A conductive film that reflects visible light is preferably used as the electrode through which light is not extracted.

When a voltage higher than the threshold voltage of the light-emitting element is applied between the lower electrode 131 and the upper electrode 135, holes are injected to the EL layer 133 from the anode side and electrons are injected to the EL layer 133 from the cathode side. The injected electrons and holes are recombined in the EL layer 133 and a light-emitting substance contained in the EL layer 133 emits light.

The EL layer 133 includes at least a light-emitting layer. In addition to the light-emitting layer, the EL layer 133 may further include one or more layers containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

Either a low molecular compound or a high molecular compound can be used for the EL layer 133, and an inorganic compound may be used. Each of the layers included in the EL layer 133 can be formed by any of the following methods: an evaporation method (including a vacuum evaporation method), a transfer method, a printing method, an inkjet method, a coating method, and the like.

The light-emitting element may contain two or more kinds of light-emitting substances. Thus, for example, a light-emitting element that emits white light can be achieved. For example, light-emitting substances are selected so that two or more light-emitting substances emit complementary colors to obtain white light emission. A light-emitting substance that emits red (R) light, green (G) light, blue (B) light, yellow (Y) light, or orange (O) light or a light-emitting substance that emits light containing spectral components of two or more of R light, G light, and B light can be used, for example. A light-emitting substance that emits blue light and a light-emitting substance that emits yellow light may be used, for example. At this time, the emission spectrum of the light-emitting substance that emits yellow light preferably contains spectral components of G light and R light. The emission spectrum of the light-emitting element 830 preferably has two or more peaks in the wavelength range in a visible region (e.g., greater than or equal to 350 nm and less than or equal to 750 nm or greater than or equal to 400 nm and less than or equal to 800 nm).

The EL layer 133 may include a plurality of light-emitting layers. In the EL layer 133, the plurality of light-emitting layers may be stacked in contact with one another or may be stacked with a separation layer provided therebetween. The separation layer may be provided between a fluorescent layer and a phosphorescent layer, for example.

The separation layer can be provided, for example, to prevent energy transfer by the Dexter mechanism (particularly triplet energy transfer) from a phosphorescent material or the like in an excited state which is generated in the phosphorescent layer to a fluorescent material or the like in the fluorescent layer. The thickness of the separation layer may be several nanometers. Specifically, the thickness of the separation layer may be greater than or equal to 0.1 nm and less than or equal to 20 nm, greater than or equal to 1 nm and less than or equal to 10 nm, or greater than or equal to 1 nm and less than or equal to 5 nm. The separation layer contains a single material (preferably, a bipolar substance) or a plurality of materials (preferably, a hole-transport material and an electron-transport material).

The separation layer may be formed using a material contained in a light-emitting layer in contact with the separation layer. This facilitates the manufacture of the light-emitting element and reduces the drive voltage. For example, in the case where the phosphorescent layer contains a host material, an assist material, and the phosphorescent material (a guest material), the separation layer may contain the host material and the assist material. In other words, the separation layer includes a region not containing the phosphorescent material and the phosphorescent layer includes a region containing the phosphorescent material in the above structure. Accordingly, the separation layer and the phosphorescent layer can be evaporated separately depending on whether a phosphorescent material is used or not. With such a structure, the separation layer and the phosphorescent layer can be formed in the same chamber. Thus, the manufacturing cost can be reduced.

### <Separate Coloring>

FIG. 2A shows an example in which a light-emitting element is formed using a separate coloring method is used as the display element 103. Since the EL layers 133 and the like have different colors, different colors can be emitted from the light-emitting elements for each element region 102. For example, a light-emitting layer which emits red, yellow, green, or blue light can be used as the layer containing a light-emitting organic compound.

### <White EL>

FIG. 2B shows an example in which a light-emitting element using a white-light-emitting material is used for the EL layer 133 of the display element 103. The light-emitting element may be a single element including one EL layer 133 or a tandem element in which a plurality of EL layers 133 are stacked with a charge generation layer provided therebetween. For example, a white-light-emitting tandem element that includes a fluorescence-emitting unit including a blue light-emitting layer and a phosphorescence-emitting unit including a green light-emitting layer and a red light-emitting layer can be used.

### <Microcavity>

FIG. 2C shows an example in which a light-emitting element having a microcavity structure is used as the display element 103. For example, the microcavity structure may be formed using the lower electrode and the upper electrode of the light-emitting element so that light with a specific wavelength can be extracted from the light-emitting element efficiently.

Specifically, a reflective film which reflects visible light is used as the lower electrode, and a semi-transmissive and semi-reflective film which transmits part of visible light and reflects part of visible light is used as the upper electrode. The upper electrode and the lower electrode are arranged so that light with a specific wavelength can be extracted efficiently.

A first lower electrode 131R, a second lower electrode 131G, and a third lower electrode 131B function as a lower electrode or a cathode in each light-emitting element. The lower electrode 131R, the second lower electrode 131G, and the third lower electrode 131B each have a function of adjusting the optical path length so that desired light emitted from light-emitting layers resonates and its wavelength can be amplified. Instead of the lower electrode, at least one layer included in the light-emitting element can be used to adjust the optical path length.

The conductive film that transmits visible light can be formed using, for example, indium oxide, indium tin oxide (ITO), indium zinc oxide, zinc oxide (ZnO), or zinc oxide to which gallium is added. Alternatively, a film of a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be formed thin so as to have a light-transmitting property. A stack of any of the above materials can be used as the conductive layer. For example, a stacked film of ITO and an alloy of silver and magnesium is preferably used, in which case conductivity can be increased. Further alternatively, graphene or the like may be used.

For the conductive material that reflects visible light, for example, a metal material such as aluminum, gold, platinum, silver, nickel, tungsten, chromium, molybdenum, iron, cobalt, copper, or palladium or an alloy containing any of these metal materials can be used. Lanthanum, neodymium, germanium, or the like may be added to the metal material or the alloy. Furthermore, an alloy containing aluminum (an aluminum alloy) such as an alloy of aluminum and titanium, an alloy of aluminum and nickel, an alloy of aluminum and neodymium, or an alloy of aluminum, nickel, and lanthanum (Al—Ni—La), or an alloy containing silver such as an alloy of silver and copper, an alloy of silver, palladium, and copper (Ag—Pd—Cu, also referred to as APC), or an alloy of silver and magnesium can be used for the conductive film. An alloy of silver and copper is preferable because of its high heat resistance. A metal film or a metal oxide film is stacked on an aluminum alloy film, whereby oxidation of the aluminum alloy film can be suppressed. Examples of a material for the metal film or the metal oxide film are titanium and titanium oxide. Alternatively, the conductive film having a property of property of transmitting visible light and a film containing any of the above metal materials may be stacked. For example, a stacked film of silver and ITO or a stacked film of an alloy of silver and magnesium and ITO can be used.

In the case of using the microcavity structure, a semi-transmissive and semi-reflective electrode can be used as the upper electrode of the light-emitting element. The semi-transmissive semi-reflective electrode is formed using a reflective conductive material and a light-transmitting conductive material. As the conductive materials, a conductive material having a visible light reflectivity of higher than or equal to 20% and lower than or equal to 80%, preferably higher than or equal to 40% and lower than or equal to 70%, and a resistivity of lower than or equal to 1×10⁻² Ωcm can be used. The semi-transmissive semi-reflective electrode can be formed using one or more kinds of conductive metals, conductive alloys, conductive compounds, and the like. In particular, a material with a small work function (3.8 eV or less) is preferable. For example, aluminum, silver, an element belonging to Group 1 or 2 of the periodic table (e.g., an alkali metal such as lithium or cesium, an alkaline earth metal such as calcium or strontium, or magnesium), an alloy containing any of these elements (e.g., Ag—Mg or Al—Li), a rare earth metal such as europium or ytterbium, and an alloy containing any of these rare earth metals.

The electrodes can be formed by an evaporation method or a sputtering method. Alternatively, a discharging method such as an ink-jet method, a printing method such as a screen printing method, or a plating method may be used.

### <Adhesive Layer 105>

The adhesive layer 105 has a function of bonding the element layers 113 and 117.

For the adhesive layer 105, an inorganic material, an organic material, a composite material of an inorganic material and an organic material, or the like can be used.

For example, a glass layer with a melting point of 400° C. or lower, preferably 300° C. or lower can be used as the adhesive layer 105. An adhesive or the like can be used for the adhesive layer 105.

For example, an organic material such as a light curable adhesive, a reactive curable adhesive, a thermosetting adhesive, and/or an anaerobic adhesive can be used for the adhesive layer 105.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin, or the like can be used for the adhesive layer 105.

### <Substrate 109>

It is desirable that the substrate 109 have heat resistance high enough to withstand a manufacturing process and a thickness and a size with which the substrate 109 can be processed using a manufacturing apparatus. The substrate which can be used as the substrate 101, which is described above, can be used as the substrate 109. Note that the second substrate preferably has a high light-transmitting property. The substrate 109 may be replaced with another one during the process.

### <Light-Blocking Layer 183>

For the light-blocking layer 183, a light-blocking material can be used. For example, a resin in which a pigment is dispersed, a resin containing a dye, or an inorganic film such as a black chromium film can be used for the light-blocking layer 183. For the light-blocking layer 183, carbon black, a metal oxide, a composite oxide containing a solid solution of a plurality of metal oxides, or the like can be used.

### <Coloring Layer 181>

The coloring layer 181 transmits light in a specific wavelength range. A color filter that transmits light in a specific wavelength range, such as red, green, blue, or yellow light, can be used, for example. Each coloring layer is formed in a desired position with any of various materials by a printing method, an inkjet method, an etching method using a photolithography method, or the like. In a white pixel, a resin such as a transparent resin or a white resin may be overlapped with the light-emitting element.

### <Polymer-Dispersed Liquid Crystal>

A polymer-dispersed liquid crystal (PDLC) is used for the polymer-dispersed liquid crystal layer 173. The polymer-dispersed liquid crystal is a liquid crystal system in which a layer where liquid crystals are dispersed in polymer is used as a liquid crystal layer. The liquid crystal is a micrograin with a diameter of approximately greater than or equal to 0.1 μm and less than or equal to 20 μm (typically approximately 1 μm). Note that a polymer-dispersed liquid crystal (PDLC) mode is employed as a driving method.

A polymer network liquid crystal (PNLC) may be used. The polymer network liquid crystal is of a liquid crystal system in which a layer where liquid crystals are continuously arranged in a polymer network is used as a liquid crystal layer.

In the polymer-dispersed liquid crystal layer 173, liquid crystal particles are dispersed in a polymer layer forming macromolecular network.

A nematic liquid crystal can be used for the liquid crystal particles.

A photocurable resin can be used for the polymer layer. The photocurable resin may be a monofunctional monomer such as acrylate or methacrylate; a polyfunctional monomer such as diacrylate, triacrylate, dimethacrylate, or trimethacrylate; or a mixture thereof. The photocurable resin may have liquid crystallinity, non-liquid crystallinity, or both of them. A resin which is cured with light having a wavelength with which the photopolymerization initiator to be used is reacted may be selected as the photocurable resin; typically, an ultraviolet curable resin can be used.

For example, the polymer-dispersed liquid crystal layer 173 can be formed in such a manner that a liquid crystal material including liquid crystal grains using nematic liquid crystal, a polymer layer using a photocurable resin, and a photopolymerization initiator is irradiated with light having a wavelength with which the photocurable resin and the photopolymerization initiator are reacted and cured.

As the photopolymerization initiator, a radical polymerization initiator which generates radicals by light irradiation, an acid generator which generates an acid by light irradiation, or a base generator which generates a base by light irradiation may be used.

The polymer-dispersed liquid crystal layer 173 can be formed by a dispenser method (a dropping method), or an injecting method in which a liquid crystal is injected using a capillary phenomenon

Since liquid crystals are not aligned in advance and incident light is not polarized in the case of using polymer dispersed liquid crystal, an alignment film and a polarizing plate are not necessarily provided.

Since an alignment film and a polarizing plate are not provided in a liquid crystal display panel using polymer dispersed liquid crystal, light is not absorbed by the alignment film and the polarizing plate; thus, a bright display screen with higher luminance can be obtained. High light use efficiency leads to reduction in power consumption. Steps and cost for providing the alignment film and the polarizing plate can be reduced, and thus higher throughput and lower cost can be realized. In addition, rubbing treatment is unnecessary because an alignment film is not provided; accordingly, dielectric breakdown caused by the rubbing treatment can be prevented and defects and damage of the display panel can be reduced in the manufacturing process. Thus, the display panel can be manufactured with high yield and productivity thereof can be improved. A transistor particularly has a possibility that electric characteristics of the transistor may fluctuate significantly owing to static electricity and deviate from the design range. Therefore, it is effective to use a polymer dispersed liquid crystal material for a display panel including a transistor.

An operation principle of polymer dispersed liquid crystal will be described. In the polymer-dispersed liquid crystal layer 173, in the case of applying no voltage between the electrode layers 175 and 171 (the state is referred to as an off state), the liquid crystal grains dispersed in the polymer layer are oriented in a random manner to cause a difference between the refractive index of the polymer and the refractive index of the liquid crystal molecule, and incident light is thus scattered by the liquid crystal grains to make the liquid crystal layer opaque and clouded.

In the case of applying voltage between the electrode layers 175 and 171 (the state is referred to as an on state), an electric field is generated in the polymer-dispersed liquid crystal layer 173, and the liquid crystal molecules in the liquid crystal grains are oriented in the direction of the electric field such that the refractive index of the polymer corresponds with the refractive index in the short axis of the liquid crystal molecule. Thus, incident light is transmitted through the polymer-dispersed liquid crystal layer 173 without being scattered by the liquid crystal grains. Therefore, the polymer-dispersed liquid crystal layer 173 transmits light and becomes transparent.

A cell gap that is the thickness of the polymer-dispersed liquid crystal layer 173 is greater than or equal to 2 μm and less than or equal to 30 μm (preferably greater than or equal to 3 μm and less than or equal to 8 μm). In this specification, the thickness of a cell gap refers to the maximum thickness (film thickness) of the polymer-dispersed liquid crystal layer 173.

As described later, the display panel of one embodiment of the present invention can exhibit a dispersion effect equivalent to that of a double-thickness polymer-dispersed liquid crystal layer 173 in the following manner: an external incident light is dispersed by the polymer-dispersed liquid crystal layer 173 and is reflected by a reflective electrode of the display element 103 to reenter the polymer-dispersed liquid crystal layer 173. Thus, a cell gap of one embodiment of the present invention can be small. The small cell gap enables the display element 107 to operate at a low voltage, which is preferable.

### <Selecting Display Mode>

In one embodiment of the present invention, either the display element 103 or 107 can be selected and operated to display images.

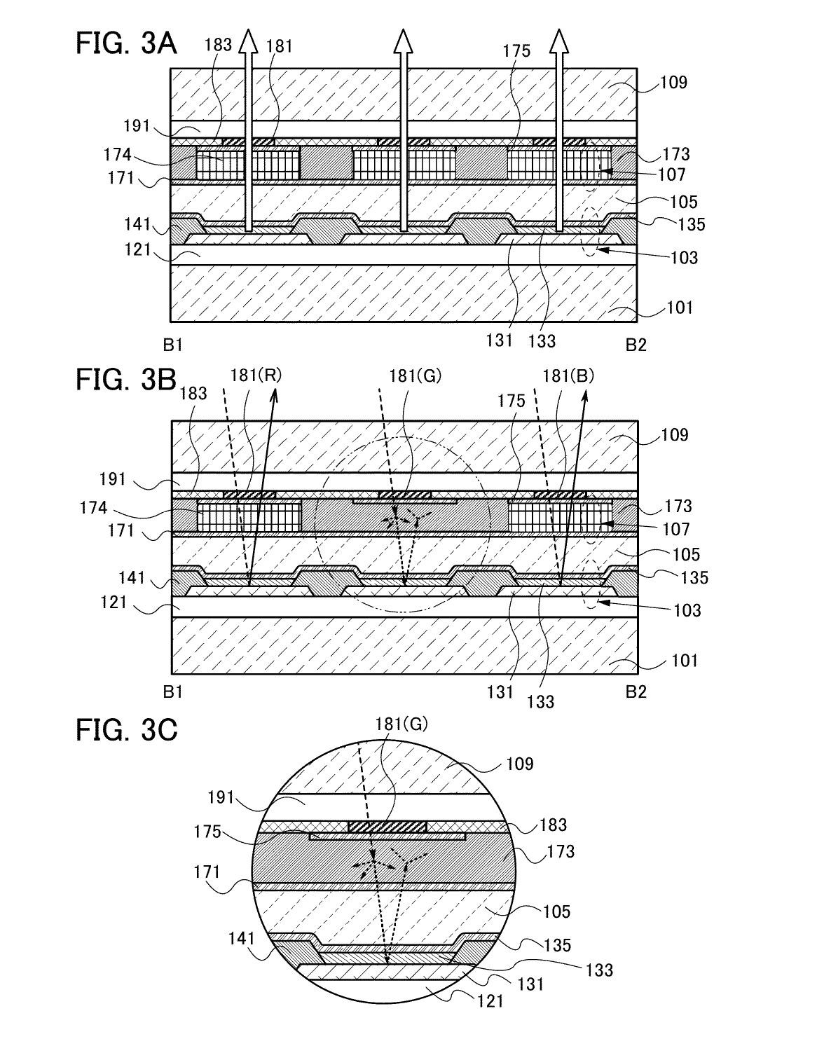

FIG. 3A shows an image display method using the display element 103. In this display method, voltage is applied to all pixels between the electrode layers 175 and 171, and the polymer-dispersed liquid crystal layer 173 is brought into a transmitting state 174, whereby the light emitted from the display element 103 is transmitted and an image is displayed. This display method is suitable to display clear and colorful moving images indoors.

Note that the polymer-dispersed liquid crystal layer 173 may disperse visible light when the display element 103 is operated to display an image. In the case where dot defects (luminescent spots) occur in the display element 103, for example, the polymer-dispersed liquid crystal layer 173 disperses light emitted from the display element 103 to decrease the intensity of the luminescence spots, so that the spots become hard to be seen.

FIGS. 3B and 3C show an image display method using the display element 107. FIG. 3C is an enlarged view of the display elements 103 and 107 in a circle with a dashed line in FIG. 3B. The display element 107 is used for displaying images utilizing external light reflection. In the example here, voltage is applied between the electrode layers 175 and 171 in each of a pixel including the red (R) coloring layer 181 and a pixel including the blue (B) coloring layer 181. The polymer-dispersed liquid crystal layers 173 below the coloring layers 181 are brought into the visible-light-transmitting state. External light entering these pixels becomes red light and blue light through the coloring layers 181. The red light and the blue light pass the polymer-dispersed liquid crystal layers 173, are reflected by the lower electrodes 131 of the display elements 103, pass the polymer-dispersed liquid crystal layers 173 and the coloring layers 181 again, and are perceived by viewers' eyes as an image.

In contrast, no voltage is applied between the electrode layers 175 and 171 of a pixel including a green (G) coloring layer 181. Thus, incident light passes the coloring layer 181 to be green and reaches the polymer-dispersed liquid crystal layer 173, and then at least part of the light is dispersed in the polymer-dispersed liquid crystal layer 173. The light that passes the polymer-dispersed liquid crystal layer 173 and reaches the lower electrode 131 of the display element 103 is also dispersed by the polymer-dispersed liquid crystal layer 173 after being reflected by the lower electrode 131 of the display element 103. The light that reenters the polymer-dispersed liquid crystal layer 173 and the coloring layer 181 with the same color is attenuated by dispersion in the polymer-dispersed liquid crystal layer 173, and is hardly extracted from the display panel. This state is a black state of the display mode.

The thickness of the coloring layer 181 in this case can be half a usual thickness in the conventional light transmission. Such a thin coloring layer is preferable for suppressing attenuation of light emitted from the display element 103. Since external light reflection is utilized in the display element 107, emission in the display element is not needed; thus, power consumption can be reduced.

The structure for displaying black on the display panel 100 is not limited to the above structure in which black is displayed when light is dispersed in the polymer-dispersed liquid crystal layer 173. For example, as shown in FIG. 2C in which the display element 103 has a microcavity structure, the display panel 100 may display black when the polymer-dispersed liquid crystal layer 173 transmits light.

A difference in phases between external light reflected by the first, second, and third lower electrodes 131R, 131G, and 131B, which then enters upper electrodes 135, and external light that enters from the polymer-dispersed liquid crystal layer 173 is λ/2. Thus, when the optimization of optical resonance is performed with a microcavity structure, these two lights are canceled in the upper electrodes 135 and are hardly extracted from the display panel 100 in some cases. This state may be regarded as black display of the display panel 100. In this case, an image can be perceived by viewers' eyes when light that is dispersed and reflected by the polymer-dispersed liquid crystal layer 173 is extracted from the coloring layer.

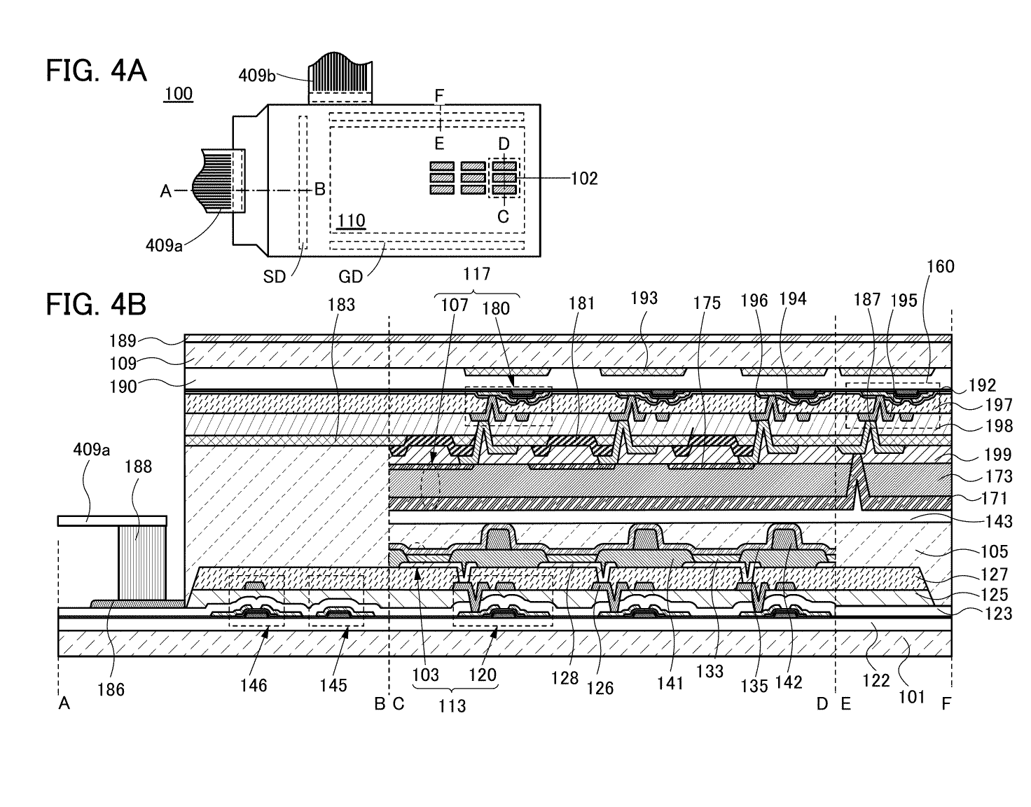

FIGS. 4A and 4B are a top view and a cross-sectional view respectively illustrating the display panel 100 in detail. Note that FIG. 4A illustrates a representative structure example including the display region 110 including the element regions 102, FPCs 409a and 409b, and driver circuits SD and GD.

The display panel in FIG. 4B is an example of the display panel 100 in FIG. 1A and includes the substrate 101, the element layers 113 and 117, and the substrate 109 which are stacked in this order. A touch sensor 189 overlaps with the substrate 109 in FIG. 4B but is not necessarily provided.

### <Insulating Films 122 and 123>

An insulating film 122 can be formed using, for example, silicon oxide or silicon oxynitride. In the case where a transistor in which an oxide semiconductor is used for a semiconductor layer is used, an oxide semiconductor film containing more oxygen than that in the stoichiometric composition is preferably used as the insulating film 122. An insulating film 123 is preferably formed using a nitride insulating film which has a function of blocking oxygen, hydrogen, water, an alkali metal, an alkaline earth metal, and the like. Owing to such a structure, electrical characteristics and reliability of the transistor in which an oxide semiconductor is used for the semiconductor layer can be enhanced.

The insulating film that can be used as the insulating film 122 can also be used as an insulating film 190. The insulating film that can be used as the insulating film 123 can also be used as an insulating film 192.

### <Planarization Insulating Films 125 and 127>

The planarization insulating films 125 and 127 can be formed using a heat-resistant organic material, such as a polyimide resin, an acrylic resin, a polyimide amide resin, a benzocyclobutene resin, a polyamide resin, or an epoxy resin. Note that the planarization insulating films 125 and 127 may be formed by stacking a plurality of insulating films including these materials.

The materials for the planarization insulating films 125 and 127 can also be used for planarization insulating films 197, 198, and 199.

### <Insulating Film 141>

For the insulating film 141, an organic resin or an inorganic insulating material can be used, for example. As the organic resin, for example, a polyimide resin, a polyamide resin, an acrylic resin, a siloxane resin, an epoxy resin, a phenol resin, or the like can be used. As the inorganic insulating material, silicon oxide, silicon oxynitride, or the like can be used, for example.

### <Spacer 142>

An insulating material can be used for the spacer 142. For example, an inorganic material, an organic material, or a stacked-layer material of an inorganic material and an organic material can be used. Specifically, a film containing silicon oxide, silicon nitride, or the like, acrylic, polyimide, a photosensitive resin, or the like can be used.

### <Display Element 103>

The display element 103 includes the lower electrode 131, the EL layer 133, and the upper electrode 135. The upper electrode 135 has a function of a common electrode. The display device illustrated in FIG. 4B is capable of displaying an image by light emission from the EL layer 133 included in the display element 103. Note that the transistor 120 is electrically connected to the display element 103 with the conductive film 126.

The coloring layer 181 is in a position to overlap with the display element 103. The light-blocking layer 183 is in a position to overlap with the insulating film 141.

The FPC 409a is electrically connected to a connection electrode 186 with an anisotropic conductive film 188 provided therebetween. The connection electrode 186 can be formed in the step of forming the electrode layer of the transistor 120 and the like. The FPC 409a can supply an image signal and the like to the driver circuit SD including a transistor 146, a capacitor 145, and the like.

### <Display Element 107>

The display element 107 includes the electrode layer 175 and the electrode layer 171 having a light-transmitting property, and the polymer-dispersed liquid crystal layer 173. The electrode layer 175 is connected to a transistor 180 in the element region 102 with conductive films 194 and 196 provided therebetween.

### <Electrode Layer 171>

The electrode layer 171 is a common electrode to which a constant voltage is supplied and is connected to a transistor 160 with conductive films 195 and 187 provided therebetween.

A light-blocking film 193 may be provided so as to overlap with the transistors 180 and 160.

### <Adhesive Layer 105>

A flexible solid material can be used for the adhesive layer 105, such as an inorganic material, an organic material, or a composite material of an inorganic material and an organic material.

The adhesive layer 105 may have a stacked-layer structure using different organic materials, different inorganic materials, or an organic material and an inorganic material.

As the inorganic material, a glass material such as glass frit, silicon oxide, silicon oxynitride, silicon nitride, or the like can be used.

As the insulating film 143, silicon oxide, silicon oxynitride, silicon nitride or the like can be used.

The display panel 100 of one embodiment of the present invention includes the display elements 103 and 107. The display element 107 contains polymer-dispersed liquid crystals and has a function of transmitting or dispersing light emitted from the display element 103. With the structure, a novel display panel with low power consumption and high convenience in which display elements can be selectively used can be provided.

This embodiment can be combined with any of the other embodiments in this specification as appropriate.

### Embodiment 2

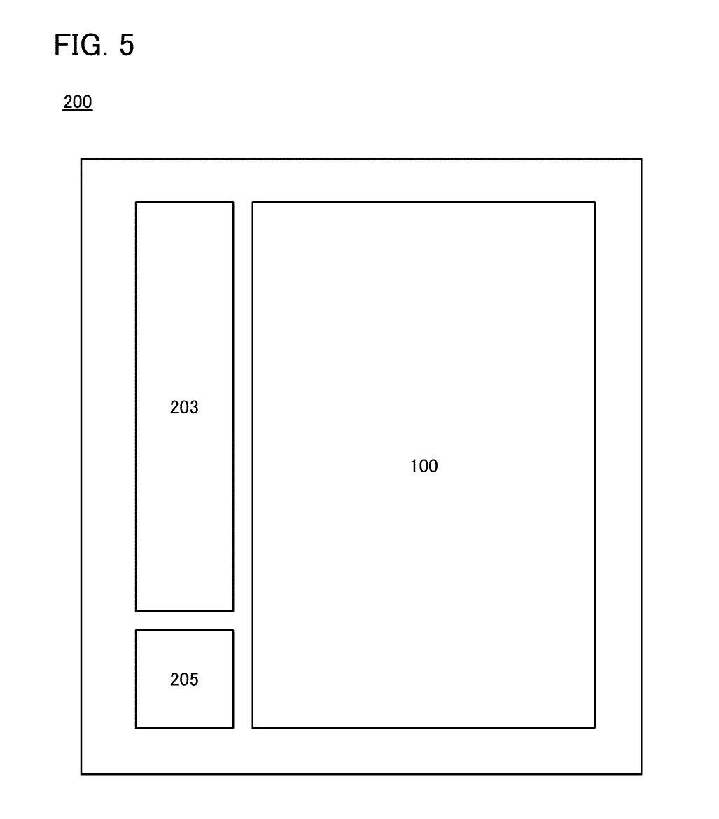

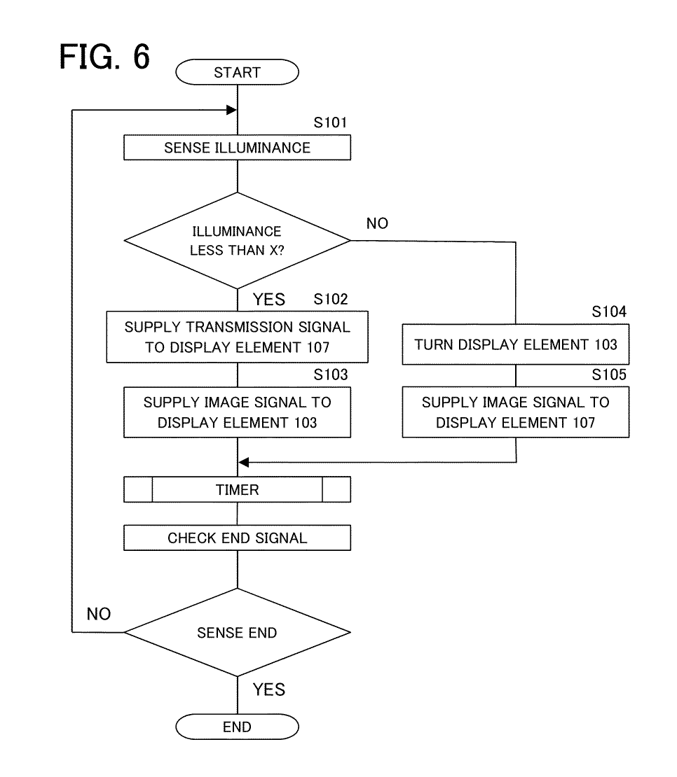

This embodiment describes one embodiment of a display device including the display panel 100 in Embodiment 1 and a driving method of the display device with reference to FIG. 5 and FIG. 6.

FIG. 5 is a block diagram illustrating a display device 200 of one embodiment of the present invention. The display device 200 includes the display panel 100, a light sensor 205, and a driving device 203.

### <Light Sensor 205>

The light sensor 205 detects illuminance and supplies the detected data to the driving device 203. For example, a photoelectric conversion element and a circuit that detects and outputs the illuminance of the environment in accordance with signals supplied from the photoelectric conversion element can be used for the light sensor 205.

Specifically, a photodiode, a CCD image sensor, a CMOS image sensor, or the like can be used as the light sensor 205.

### <Driving Device 203>

The driving device 203 determines a driving method of the display panel 100 based on the data supplied from the light sensor 205 and drives the display panel 100.

In the case where a detected illuminance is less than a predetermined value, the driving device 203 supplies an image signal to the display element 103 and supplies a signal for making the display element 107 to transmit light. In the case where the illuminance is more than or equal to the predetermined value, the driving device 203 does not make the display element 103 active and supplies image data to the display element 107.

Next, an example of a driving method of the display device 200 is described with reference to a flow chart in FIG. 6.

First, the light sensor 205 in the display device 200 detects illuminance (S101).

When the illuminance detected in S101 is less than a predetermined illuminance X, a transmission signal is supplied to the display element 107 (S102). Then, an image signal is supplied to the display element 103 to display an image (S103).

In contrast, when the illuminance detected in S101 is more than or equal to the predetermined illuminance X, the display element 103 is turned off (S104). Then, an image signal is supplied to the display element 107 to display an image (S105).

After predetermined time set using a timer or the like passes, illuminance is detected (S101) again and the steps are repeated.

The display element 103 is a self-emission type with power consumption, whereas the display element 107 can display images utilizing external light. Thus, power consumption can be greatly reduced in a high-illuminance environment where the display element 107 is used for displaying images. In addition, there is no need for users to switch display modes because the display modes are automatically changed depending on illuminance. As a result, a display device with low power consumption and high convenience can be provided.

This embodiment can be combined with any of the other embodiments in this specification as appropriate.

### Embodiment 3

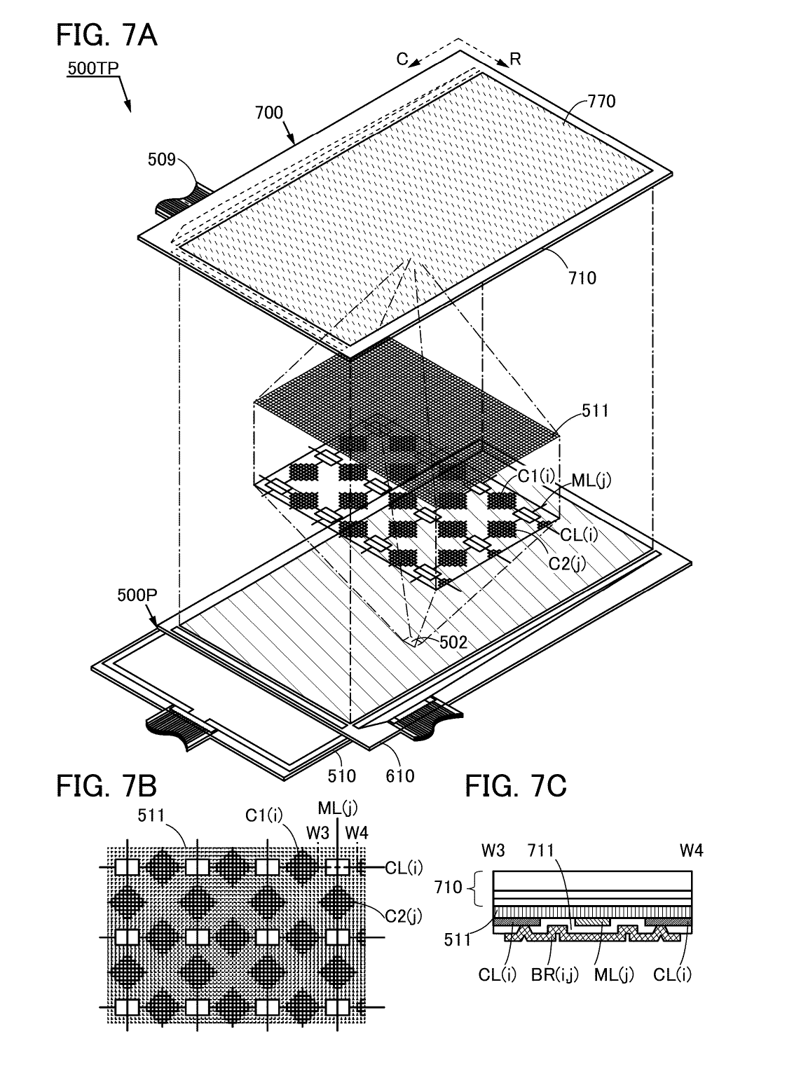

In this embodiment, a structure of an input/output device having the display panel of one embodiment of the present invention is described with reference to FIGS. 7A to 7C.

FIG. 7A is a projection view illustrating an input/output device 500TP of one embodiment of the present invention. Note that for convenience of description, part of a sensor panel 700 is enlarged. FIG. 7B is a top view illustrating part of the sensor panel 700. FIG. 7C is a cross-sectional view taken along cut line W3-W4 in FIG. 7B.

### <Structure Example of Input/Output Device>

The input/output device 500TP described in this embodiment includes a display panel 500P and the sensor panel 700 having a region overlapping with the display panel 500P (see FIG. 7A). The display panel 500P corresponds to the display panel 100 in Embodiment 1. The sensor panel 700 corresponds to the touch sensor 189 in Embodiment 1.

Individual components included in the input/output device 500TP are described below. Note that these units cannot be clearly distinguished and one unit also serves as another unit or include part of another unit in some cases.

For example, the input/output device 500TP where the sensor panel 700 overlaps with the display panel 500P serves as the sensor panel 700 and the display panel 500P. Note that the input/output device 500TP in which the sensor panel 700 overlaps with the display panel 500P is also referred to as a touch panel.

### <Display Panel>

The display panel 500P includes the pixel 502, scan lines, signal lines, and a base 510.

### <Sensor Panel>

The sensor panel 700 senses an object which approaches or touches the sensor panel 700 and supplies a sensing signal. For example, the sensor unit U senses capacitance, illuminance, magnetic force, a radio wave, pressure, or the like and supplies information based on the sensed physical value. Specifically, a capacitor, a photoelectric conversion element, a magnetic sensor element, a piezoelectric element, a resonator, or the like can be used as a sensor element.

For example, the sensor panel 700 senses a change in electrostatic capacitance between the sensor panel 700 and an object that approaches or is in contact with the sensor panel 700.

Note that when an object which has a higher dielectric constant than the air, such as a finger, approaches the conductive film in the air, electrostatic capacitance between the finger and the conductive film changes. The sensor panel 700 can sense the change in capacitance and supply sensing data. Specifically, the conductive film and a capacitor one electrode of which is connected to the conductive film can be used.

For example, distribution of charge occurs between the conductive film and the capacitor owing to the change in the electrostatic capacitance, so that the voltage the pair of electrodes of the capacitor is changed. This voltage change can be used as the sensing signal.

The sensor panel 700 includes a control line CL(i), a signal line ML(j), a first electrode C1(i), a second electrode C2(j), and a base material 710 (see FIGS. 7A and 7B).

Note that a wiring BR(i,j) is in a position where the control line CL(i) intersects with the signal line ML(j). An insulating film 711 for preventing a short circuit is provided between the wiring BR(i,j) and the signal line ML(j) (see FIG. 7C).

The signal line ML(j) can sense a control signal which is supplied to the control line CL(i) through a capacitor including the first electrode C1(i) and the second electrode C2(j), and can supply the signal as a sense signal.

A light-blocking layer 511 is provided between the control line CL(i) and the base material 710 and between the signal line ML(j) and the base material 710, for example. This can weaken external light reaching the control line CL(i) or the signal line ML(j) and decrease the intensity of the external light reflected by the control line CL(i) or the signal line ML(j).

The sensor panel 700 may be formed by depositing films for forming the sensor panel 700 over the base 710 and processing the films.

Alternatively, the sensor panel 700 may be formed in such a manner that part of the sensor panel 700 is formed over another base, and the part is transferred to the base 610.

The sensor panel 700 includes a plurality of control lines CL(i) that is supplied with control signals and extends in the row direction (the direction indicated by an arrow R in the figure) and a plurality of signal lines ML(j) that supplies sense signals and extends in the column direction (the direction indicated by an arrow C in the figure). The sensor panel 700 also includes the base 710 supporting the control lines CL(i) and the signal lines ML(j).

The sensor panel 700 includes the first electrode C1(i) electrically connected to the control line CL(i) and the second electrode C2(j) electrically connected to the signal line ML(j). The second electrode C2(j) includes a region not overlapping with the first electrode C1(i).

The first electrode C1(i) or the second electrode C2(j) includes a conductive film in which regions overlapping with the pixels 502 have light-transmitting properties. Alternatively, the first electrode C1(i) or the second electrode C2(j) includes a net-like conductive film whose openings overlap with the pixels 502.

The input/output device 500TP of this embodiment includes the sensor panel 700 and the display panel 500P including the region overlapping with the sensor panel 700. The first electrode C1(i) or the second electrode C2(j) includes the conductive film having the regions with light-transmitting properties or the openings in the regions overlapping with the pixels of the display panel 500P. The input/output device 500TP can thus sense an object getting close to the first electrode or the second electrode. A novel input/output device that is highly convenient or reliable can thus be provided.

For example, the sensor panel 700 of the input/output device 500TP can sense sensing information and supply the sensing information together with the positional information. Specifically, a user of the input/output device 500TP can make various gestures (e.g., tap, drag, swipe, and pinch in) using his/her finger or the like that approaches or is in contact with the sensor panel 700 as a pointer.

The sensor panel 700 is capable of sensing approach or contact of a finger or the like to the sensor panel 700 and supplying sensing information including the obtained position, track, or the like.

An arithmetic unit determines whether or not supplied data satisfies a predetermined condition on the basis of a program or the like and executes an instruction associated with a predetermined gesture.

A user of the sensor panel 700 can thus make the predetermined gesture and make the arithmetic unit execute instructions associated with the predetermined gesture.

The display panel 500P of the input/output device 500TP can display information V supplied from, for example, an arithmetic unit.

The sensor panel 700 of the input/output device 500TP is electrically connected to an FPC 509.

A protective layer 770 is provided on the user's side of the sensor panel 700.

For example, a ceramic coat layer or a hard coat layer can be used as the protective layer 770. Specifically, a layer containing aluminum oxide or a layer containing a UV curable resin can be used.

An anti-reflective layer that controls the intensity of external light reflected by the sensor panel 700 can be used as the protective layer 770. Specifically, a circular polarizing plate or the like can be used.

### <Wiring>

The sensor panel 700 includes wirings. The wirings include the control line CL(i), the signal line ML(j), and the like.

A conductive material can be used for the wirings and the like.

For example, an inorganic conductive material, an organic conductive material, metal, conductive ceramics, or the like can be used for the wiring.

Specifically, a metal element selected from aluminum, gold, platinum, silver, chromium, tantalum, titanium, molybdenum, tungsten, nickel, iron, cobalt, yttrium, zirconium, palladium, and manganese; an alloy including any of the above metal elements; an alloy including any of the above metal elements in combination; or the like can be used for the wiring. In particular, one or more elements selected from aluminum, chromium, copper, tantalum, titanium, molybdenum, and tungsten are preferably contained. In particular, an alloy of copper and manganese is suitably used in microfabrication with the use of wet etching.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, or the like can be used.

A stacked structure in which a film of an element selected from titanium, tantalum, tungsten, molybdenum, chromium, neodymium, and scandium, an alloy film including some of these elements, or a nitride film of any of these elements is stacked over an aluminum film can be used.

A conductive oxide such as indium oxide, indium tin oxide, indium zinc oxide, zinc oxide, or zinc oxide to which gallium is added can be used.

Graphene or graphite can be used. The film including graphene can be formed, for example, by reducing a film containing graphene oxide. As a reducing method, a method using heat, a method using a reducing agent, or the like can be employed.

A conductive macromolecule can be used.

### <Base>

The base 710 supports the first electrode C1(i) and the second electrode C2(j).

There is no particular limitation on the base 710 as long as the base 710 has heat resistance high enough to withstand a manufacturing process and a thickness and a size which can be used in a manufacturing apparatus. In particular, use of a flexible material as the base 710 enables the sensor panel 700 to be folded or unfolded. Note that in the case where the sensor panel 700 is positioned on a side where the display portion 500P displays an image, a light-transmitting material is used as the base 710.

For the base 710, an organic material, an inorganic material, a composite material of an organic material and an inorganic material, or the like can be used.

For example, an inorganic material such as glass, a ceramic, or a metal can be used for the base 710.

Specifically, non-alkali glass, soda-lime glass, potash glass, crystal glass, or the like can be used for the base 710.

Specifically, a metal oxide film, a metal nitride film, a metal oxynitride film, or the like can be used for the base 710. For example, silicon oxide, silicon nitride, silicon oxynitride, an alumina film, or the like can be used for the base 710.

For example, an organic material such as a resin, a resin film, or plastic can be used for the base 710.

Specifically, a resin film or resin plate of polyester, polyolefin, polyamide, polyimide, polycarbonate, an acrylic resin, or the like can be used for the base 710.

For example, a composite material such as a resin film to which a thin glass plate or a film of an inorganic material is attached can be used as the base 710.

For example, a composite material formed by dispersing a fibrous or particulate metal, glass, inorganic material, or the like into a resin film can be used as the base 710.

For example, a composite material formed by dispersing a fibrous or particulate resin, organic material, or the like into an inorganic material can be used as the base 710.

A single-layer material or a stacked-layer material in which a plurality of layers are stacked can be used for the base 710. For example, a stacked-layer material including a base and an insulating layer that prevents diffusion of impurities contained in the base can be used for the base 710.

Specifically, a stacked-layer material in which glass and one or a plurality of films that prevent diffusion of impurities contained in the glass and that are selected from a silicon oxide film, a silicon nitride film, a silicon oxynitride film, and the like are stacked can be used for the base 710.

Alternatively, a stacked-layer material in which a resin and a film that prevents diffusion of impurities contained in the resin, such as a silicon oxide film, a silicon nitride film, a silicon oxynitride film, and the like are stacked can be used for the base 710.

This embodiment can be combined with any of the other embodiments in this specification as appropriate.

### Embodiment 4

### Structure of Oxide Semiconductor

In this embodiment, a structure of an oxide semiconductor which can be used for one embodiment of the present invention is described.

In this specification, the term “parallel” indicates that the angle formed between two straight lines is greater than or equal to −10° and less than or equal to 10°, and thus includes greater than or equal to −5° and less than or equal to 5°. The term “substantially parallel” indicates that the angle formed between two straight lines is greater than or equal to −30° and less than or equal to 30°. A term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and thus includes greater than or equal to 85° and less than or equal to 95°. A term “substantially perpendicular” indicates that the angle formed between two straight lines is greater than or equal to 60° and less than or equal to 120°.

In this specification, trigonal and rhombohedral crystal systems are included in a hexagonal crystal system.

An oxide semiconductor is classified into, for example, a non-single-crystal oxide semiconductor and a single crystal oxide semiconductor. Alternatively, an oxide semiconductor is classified into, for example, a crystalline oxide semiconductor and an amorphous oxide semiconductor.

Examples of a non-single-crystal oxide semiconductor include a c-axis aligned crystalline oxide semiconductor (CAAC-OS), a polycrystalline oxide semiconductor, a microcrystalline oxide semiconductor, and an amorphous oxide semiconductor. In addition, examples of a crystalline oxide semiconductor include a single crystal oxide semiconductor, a CAAC-OS, a polycrystalline oxide semiconductor, and a microcrystalline oxide semiconductor.

First, a CAAC-OS is described.

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

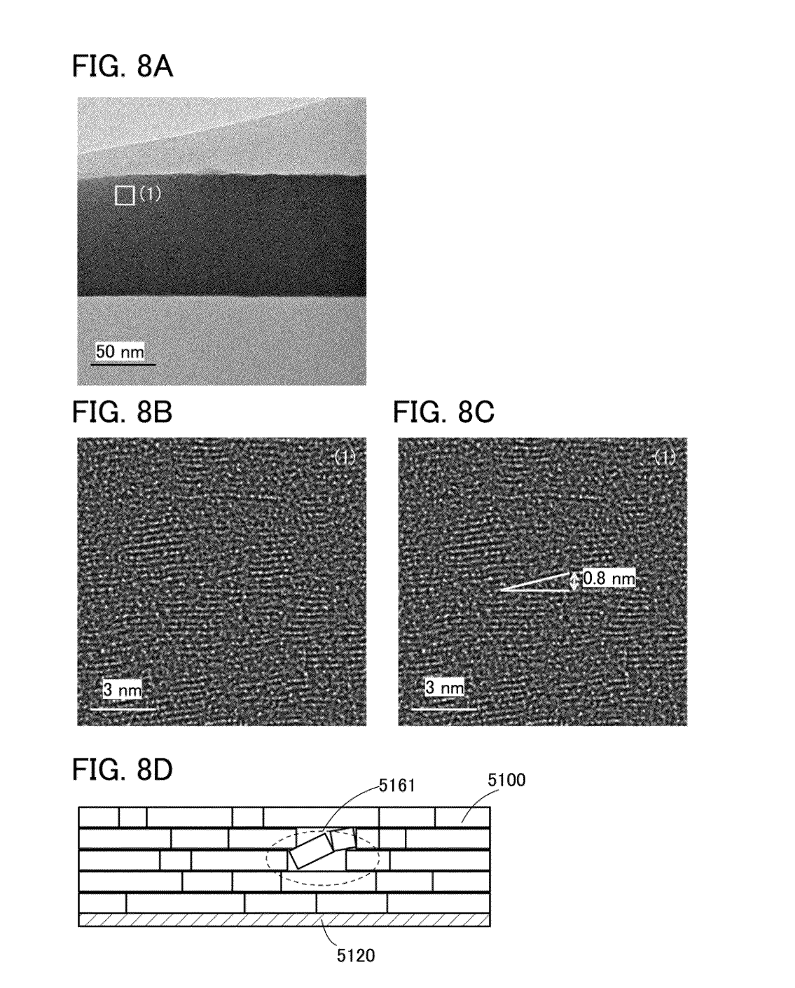

FIG. 8A shows an example of a high-resolution TEM image of a cross section of the CAAC-OS which is obtained from a direction substantially parallel to the sample surface. Here, the TEM image is obtained with a spherical aberration corrector function. The high-resolution TEM image obtained with a spherical aberration corrector function is particularly referred to as a Cs-corrected high-resolution TEM image in the following description. Note that the Cs-corrected high-resolution TEM image can be obtained with, for example, an atomic resolution analytical electron microscope JEM-ARM200F manufactured by JEOL Ltd.

FIG. 8B is an enlarged Cs-corrected high-resolution TEM image of a region (1) in FIG. 8A. FIG. 8B shows that metal atoms are arranged in a layered manner in a pellet. Each metal atom layer has a configuration reflecting unevenness of a surface over which the CAAC-OS is formed (hereinafter, the surface is referred to as a formation surface) or a top surface of the CAAC-OS, and is arranged parallel to the formation surface or the top surface of the CAAC-OS.

As shown in FIG. 8B, the CAAC-OS has a characteristic atomic arrangement. The characteristic atomic arrangement is denoted by an auxiliary line in FIG. 8C. FIGS. 8B and 8C prove that the size of a pellet is approximately 1 nm to 3 nm, and the size of a space caused by tilt of the pellets is approximately 0.8 nm. Therefore, the pellet can also be referred to as a nanocrystal (nc).

Here, according to the Cs-corrected high-resolution TEM images, the schematic arrangement of pellets 5100 of a CAAC-OS over a substrate 5120 is illustrated by such a structure in which bricks or blocks are stacked (see FIG. 8D). The part in which the pellets are tilted as observed in FIG. 8C corresponds to a region 5161 shown in FIG. 8D.

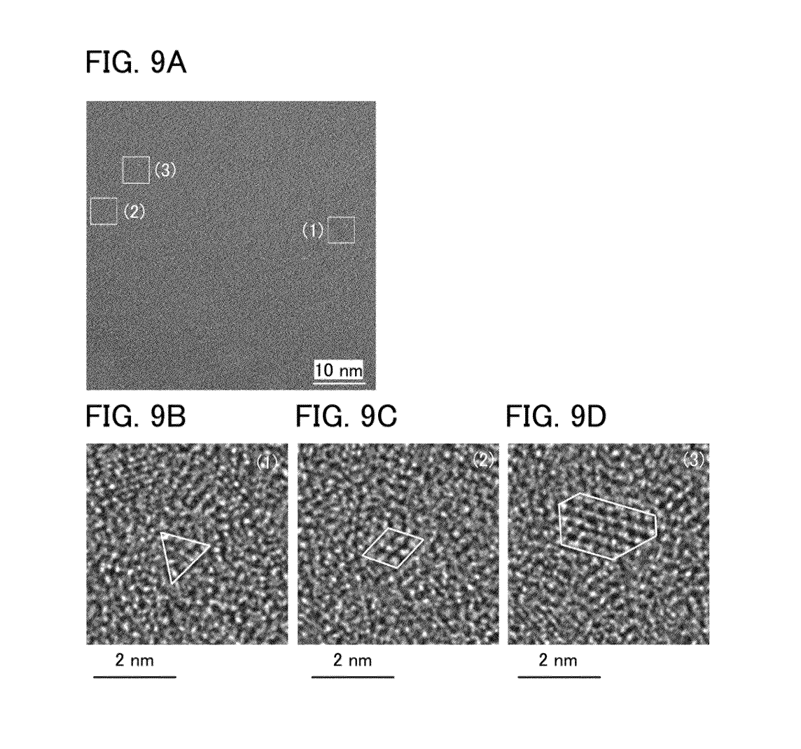

For example, as shown in FIG. 9A, a Cs-corrected high-resolution TEM image of a plane of the CAAC-OS obtained from a direction substantially perpendicular to the sample surface is observed. FIGS. 9B, 9C, and 9D are enlarged Cs-corrected high-resolution TEM images of regions (1), (2), and (3) in FIG. 9A, respectively. FIGS. 9B, 9C, and 9D indicate that metal atoms are arranged in a triangular, quadrangular, or hexagonal configuration in a pellet. However, there is no regularity of arrangement of metal atoms between different pellets.

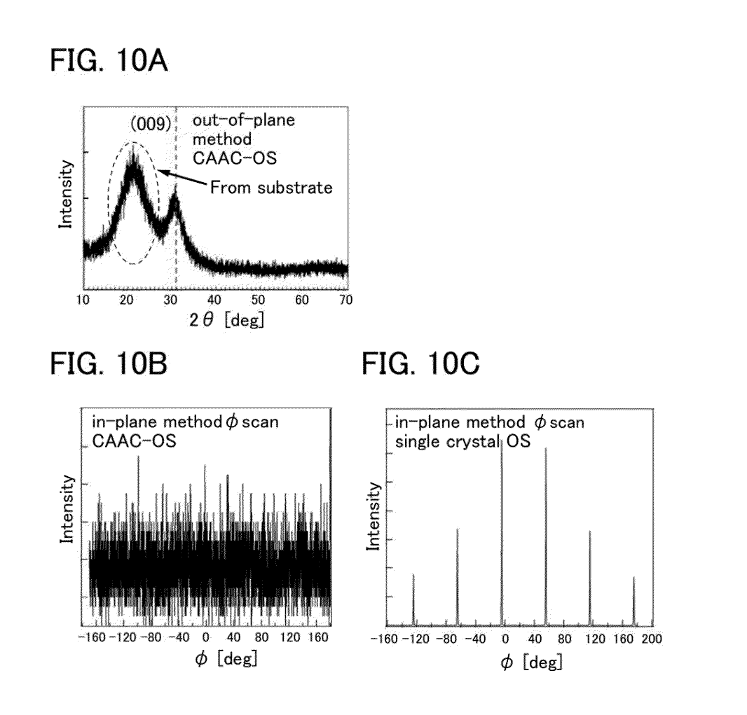

For example, when the structure of a CAAC-OS including an InGaZnO₄ crystal is analyzed by an out-of-plane method using an X-ray diffraction (XRD) apparatus, a peak appears at a diffraction angle (2θ) of around 31° as shown in FIG. 10A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS including an InGaZnO₄ crystal by an out-of-plane method, another peak may appear when 2θ is around 36°, in addition to the peak at 2θ of around 31°. The peak at 2θ of around 36° indicates that a crystal having no c-axis alignment is included in part of the CAAC-OS. It is preferable that in the CAAC-OS, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is attributed to the (110) plane of the InGaZnO₄ crystal. In the case of the CAAC-OS, when analysis (φ scan) is performed with 2θ fixed at around 56° and with the sample rotated using a normal vector of the sample surface as an axis (φ axis), as shown in FIG. 10B, a peak is not clearly observed. In contrast, in the case of a single crystal oxide semiconductor of InGaZnO₄, when φ scan is performed with 2θ fixed at around 56°, as shown in FIG. 10C, six peaks which are derived from crystal planes equivalent to the (110) plane are observed. Accordingly, the structural analysis using XRD shows that the directions of a-axes and b-axes are different in the CAAC-OS.

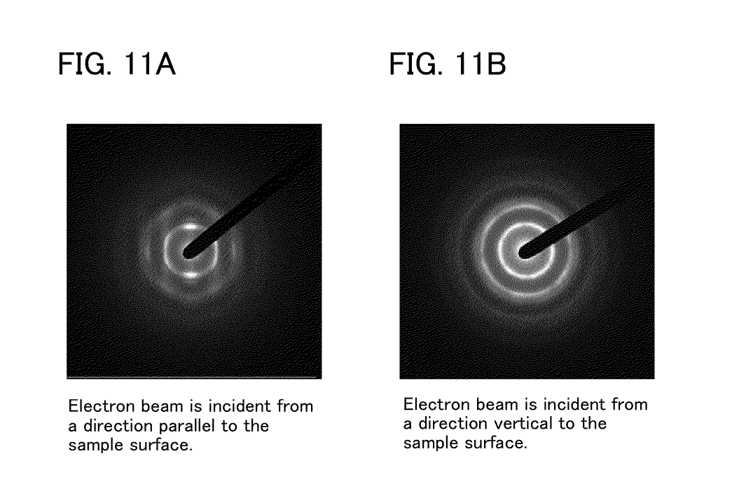

Next, FIG. 11A shows a diffraction pattern (also referred to as a selected-area transmission electron diffraction pattern) obtained in such a manner that an electron beam with a probe diameter of 300 nm is incident on an In—Ga—Zn oxide that is a CAAC-OS in a direction parallel to the sample surface. As shown in FIG. 11A, for example, spots derived from the (009) plane of an InGaZnO₄ crystal are observed. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 11B shows a diffraction pattern obtained in such a manner that an electron beam with a probe diameter of 300 nm is incident on the same sample in a direction perpendicular to the sample surface. As shown in FIG. 11B, a ring-like diffraction pattern is observed. Thus, the electron diffraction also indicates that the a-axes and b-axes of the pellets included in the CAAC-OS do not have regular alignment. The first ring in FIG. 11B is considered to be derived from the (010) plane, the (100) plane, and the like of the InGaZnO₄ crystal. The second ring in FIG. 11B is considered to be derived from the (110) plane and the like.

Since the c-axes of the pellets (nanocrystals) are aligned in a direction substantially perpendicular to the formation surface or the top surface in the above manner, the CAAC-OS can also be referred to as an oxide semiconductor including c-axis aligned nanocrystals (CANC).

The CAAC-OS is an oxide semiconductor with a low impurity concentration. The impurity means an element other than the main components of the oxide semiconductor, such as hydrogen, carbon, silicon, or a transition metal element. An element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity. Additionally, the impurity contained in the oxide semiconductor might serve as a carrier trap or a carrier generation source.

Moreover, the CAAC-OS is an oxide semiconductor having a low density of defect states. For example, oxygen vacancies in the oxide semiconductor serve as carrier traps or serve as carrier generation sources when hydrogen is captured therein.

In a transistor using the CAAC-OS, change in electrical characteristics due to irradiation with visible light or ultraviolet light is small.

Next, a microcrystalline oxide semiconductor is described.

A microcrystalline oxide semiconductor has a region in which a crystal part is observed and a region in which a crystal part is not clearly observed in a high-resolution TEM image. In most cases, the size of a crystal part included in the microcrystalline oxide semiconductor is greater than or equal to 1 nm and less than or equal to 100 nm, or greater than or equal to 1 nm and less than or equal to 10 nm. An oxide semiconductor including a nanocrystal that is a microcrystal with a size greater than or equal to 1 nm and less than or equal to 10 nm, or a size greater than or equal to 1 nm and less than or equal to 3 nm is specifically referred to as a nanocrystalline oxide semiconductor (nc-OS). In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not ordered. Accordingly, the nc-OS cannot be distinguished from an amorphous oxide semiconductor, depending on an analysis method. For example, when the nc-OS is subjected to structural analysis by an out-of-plane method with an XRD apparatus using an X-ray having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet (the electron diffraction is also referred to as selected-area electron diffraction). Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots is shown in a ring-like region in some cases.

Since there is no regularity of crystal orientation between the pellets (nanocrystals) as mentioned above, the nc-OS can also be referred to as an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an amorphous oxide semiconductor. Note that there is no regularity of crystal orientation between different pellets in the nc-OS. Therefore, the nc-OS has a higher density of defect states than the CAAC-OS.

Next, an amorphous oxide semiconductor is described.

The amorphous oxide semiconductor is an oxide semiconductor having disordered atomic arrangement and no crystal part and exemplified by an oxide semiconductor which exists in an amorphous state as quartz.

In a high-resolution TEM image of the amorphous oxide semiconductor, crystal parts cannot be found.

When the amorphous oxide semiconductor is subjected to structural analysis by an out-of-plane method with an XRD apparatus, a peak which shows a crystal plane does not appear. A halo pattern is observed when the amorphous oxide semiconductor is subjected to electron diffraction. Furthermore, a spot is not observed and a halo pattern appears when the amorphous oxide semiconductor is subjected to nanobeam electron diffraction.

There are various understandings of an amorphous structure. For example, a structure whose atomic arrangement does not have ordering at all is called a completely amorphous structure. Meanwhile, a structure which has ordering until the nearest neighbor atomic distance or the second-nearest neighbor atomic distance but does not have long-range ordering is also called an amorphous structure. Therefore, the strictest definition does not permit an oxide semiconductor to be called an amorphous oxide semiconductor as long as even a negligible degree of ordering is present in an atomic arrangement. At least an oxide semiconductor having long-term ordering cannot be called an amorphous oxide semiconductor. Accordingly, because of the presence of crystal part, for example, a CAAC-OS and an nc-OS cannot be called an amorphous oxide semiconductor or a completely amorphous oxide semiconductor.

Note that an oxide semiconductor may have a structure having physical properties intermediate between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be observed.

Furthermore, in the high-resolution TEM image, there are a region where a crystal part is clearly observed and a region where a crystal part is not observed.

A difference in effect of electron irradiation between structures of an oxide semiconductor is described below.

An a-like OS, an nc-OS, and a CAAC-OS are prepared. Each of the samples is an In—Ga—Zn oxide.

First, a high-resolution cross-sectional TEM image of each sample is obtained. The high-resolution cross-sectional TEM images show that all the samples have crystal parts.

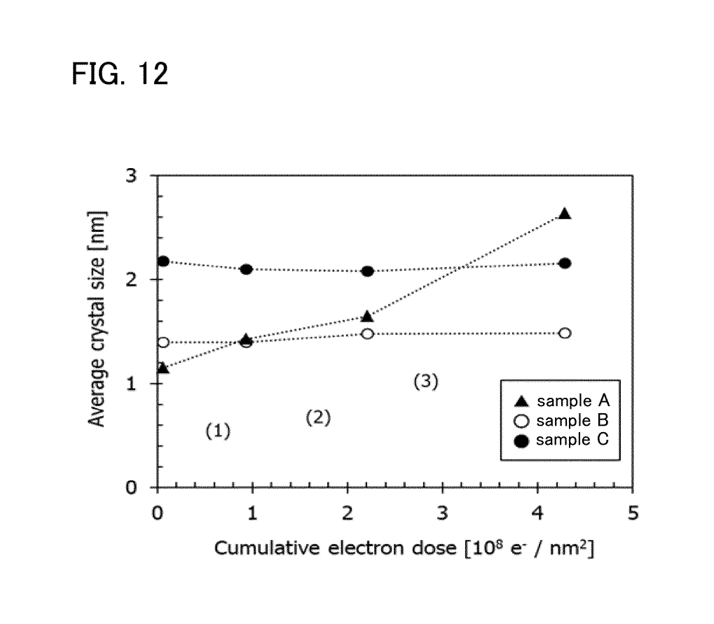

Then, the size of the crystal part of each sample is measured. FIG. 12 shows the change in the average size of crystal parts (at 22 points to 45 points) in each sample. FIG. 12 indicates that the crystal part size in the a-like OS increases with an increase in the cumulative electron dose. Specifically, as shown by (1) in FIG. 12, a crystal part of approximately 1.2 nm at the start of TEM observation (the crystal part is also referred to as an initial nucleus) grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm² regardless of the cumulative electron dose. Specifically, as shown by (2) in FIG. 12, the average crystal size is approximately 1.4 nm regardless of the observation time by TEM. Furthermore, as shown by (3) in FIG. 12, the average crystal size is approximately 2.1 nm regardless of the observation time by TEM.

In this manner, growth of the crystal part occurs due to the crystallization of the a-like OS, which is induced by a slight amount of electron beam employed in the TEM observation. In contrast, in the nc-OS and the CAAC-OS that have good quality, crystallization hardly occurs by a slight amount of electron beam used for TEM observation.

Note that the crystal part size in the a-like OS and the nc-OS can be measured using high-resolution TEM images. For example, an InGaZnO₄ crystal has a layered structure in which two Ga—Zn—O layers are included between In—O layers. A unit cell of the InGaZnO₄ crystal has a structure in which nine layers including three In—O layers and six Ga—Zn—O layers are stacked in the c-axis direction. Accordingly, the distance between the adjacent layers is equivalent to the lattice spacing on the (009) plane (also referred to as d value). The value is calculated to be 0.29 nm from crystal structural analysis. Thus, focusing on lattice fringes in the high-resolution TEM image, each of lattice fringes in which the lattice spacing therebetween is greater than or equal to 0.28 nm and less than or equal to 0.30 nm corresponds to the a-b plane of the InGaZnO₄ crystal.

Furthermore, the density of an oxide semiconductor varies depending on the structure in some cases. For example, when the composition of an oxide semiconductor is determined, the structure of the oxide semiconductor can be expected by comparing the density of the oxide semiconductor with the density of a single crystal oxide semiconductor having the same composition as the oxide semiconductor. For example, the density of the a-like OS is higher than or equal to 78.6% and lower than 92.3% of the density of the single crystal oxide semiconductor having the same composition. For example, the density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

Specific examples of the above description are given. For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

Note that an oxide semiconductor may be a stacked film including two or more films of an amorphous oxide semiconductor, an a-like OS, a microcrystalline oxide semiconductor, and a CAAC-OS, for example.

An oxide semiconductor having a low impurity concentration and a low density of defect states (a small number of oxygen vacancies) can have low carrier density. Therefore, such an oxide semiconductor is referred to as a highly purified intrinsic or substantially highly purified intrinsic oxide semiconductor. A CAAC-OS and an nc-OS have a low impurity concentration and a low density of defect states as compared to an a-like OS and an amorphous oxide semiconductor. That is, a CAAC-OS and an nc-OS are likely to be highly purified intrinsic or substantially highly purified intrinsic oxide semiconductors. Thus, a transistor including a CAAC-OS or an nc-OS rarely has negative threshold voltage (is rarely normally on). The highly purified intrinsic or substantially highly purified intrinsic oxide semiconductor has few carrier traps. Therefore, a transistor including a CAAC-OS or an nc-OS has small variation in electrical characteristics and high reliability. An electric charge trapped by the carrier traps in the oxide semiconductor takes a long time to be released. The trapped electric charge may behave like a fixed electric charge. Thus, the transistor which includes the oxide semiconductor having a high impurity concentration and a high density of defect states might have unstable electrical characteristics.

### <Deposition Model>

Examples of deposition models of a CAAC-OS and an nc-OS are described below.

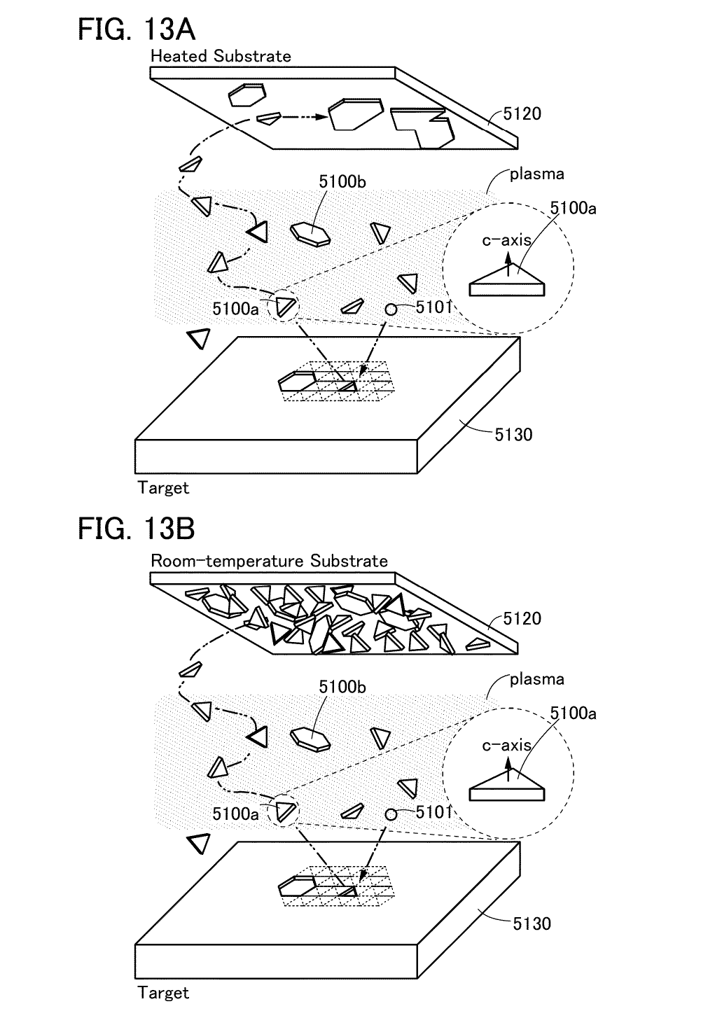

FIG. 13A is a schematic view of the inside of a deposition chamber where a CAAC-OS is deposited by a sputtering method.

A target 5130 is attached to a backing plate. A plurality of magnets is provided to face the target 5130 with the backing plate positioned therebetween. The plurality of magnets generates a magnetic field. A sputtering method in which the disposition rate is increased by utilizing a magnetic field of magnets is referred to as a magnetron sputtering method.

The target 5130 has a polycrystalline structure in which a cleavage plane exists in at least one crystal grain.

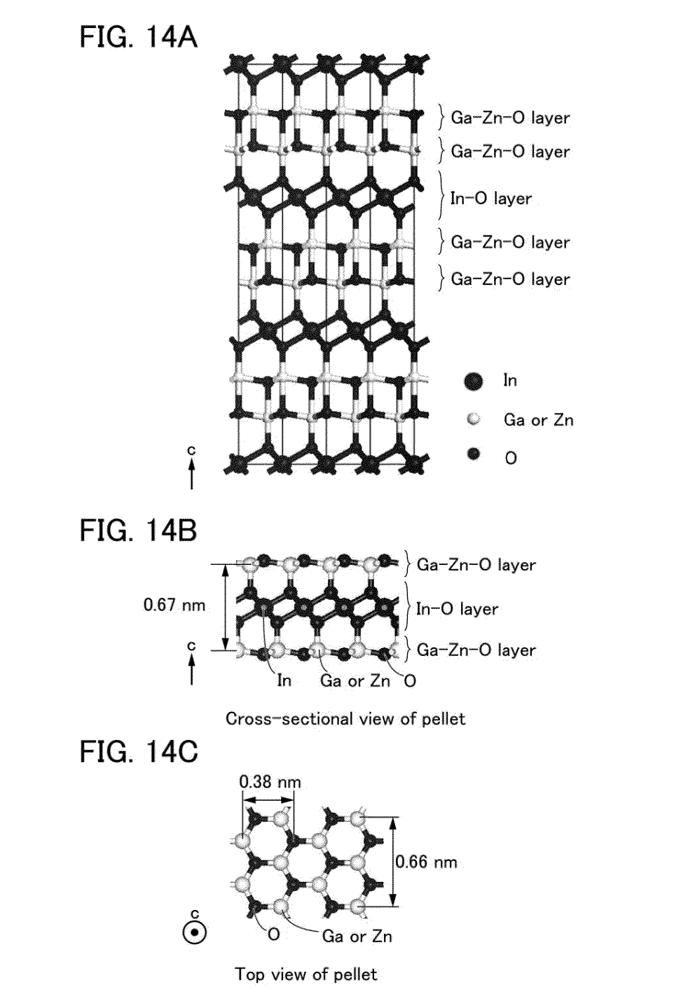

A cleavage plane of the target 5130 including an In—Ga—Zn oxide is described as an example. FIG. 14A shows a structure of an InGaZnO₄ crystal included in the target 5130. Note that FIG. 14A shows a structure of the case where the InGaZnO₄ crystal is observed from a direction parallel to the b-axis when the c-axis is in an upward direction.

FIG. 14A indicates that oxygen atoms in a Ga—Zn—O layer are positioned close to those in an adjacent Ga—Zn—O layer. The oxygen atoms have negative charge, whereby the two Ga—Zn—O layers repel each other. As a result, the InGaZnO₄ crystal has a cleavage plane between the two adjacent Ga—Zn—O layers.

The substrate 5120 is placed to face the target 5130, and the distance d (also referred to as a target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 5 vol % or higher) and the pressure in the deposition chamber is controlled to be higher than or equal to 0.01 Pa and lower than or equal to 100 Pa, preferably higher than or equal to 0.1 Pa and lower than or equal to 10 Pa. Here, discharge starts by application of a voltage at a certain value or higher to the target 5130, and plasma is observed. The magnetic field forms a high-density plasma region in the vicinity of the target 5130. In the high-density plasma region, the deposition gas is ionized, so that an ion 5101 is generated. Examples of the ion 5101 include an oxygen cation (O⁺) and an argon cation (Ar⁺).

The ion 5101 is accelerated toward the target 5130 side by an electric field, and then collides with the target 5130. At this time, a pellet 5100a and a pellet 5100b which are flat-plate-like (pellet-like) sputtered particles are separated and sputtered from the cleavage plane. Note that structures of the pellet 5100a and the pellet 5100b may be distorted by an impact of collision of the ion 5101.

The pellet 5100a is a flat-plate-like (pellet-like) sputtered particle having a triangle plane, e.g., regular triangle plane. The pellet 5100b is a flat-plate-like (pellet-like) sputtered particle having a hexagon plane, e.g., regular hexagon plane. Note that flat-plate-like (pellet-like) sputtered particles such as the pellet 5100a and the pellet 5100b are collectively called pellets 5100. The shape of a flat plane of the pellet 5100 is not limited to a triangle or a hexagon. For example, the flat plane may have a shape formed by combining two or more triangles. For example, a quadrangle (e.g., rhombus) may be formed by combining two triangles (e.g., regular triangles).

The thickness of the pellet 5100 is determined depending on the kind of deposition gas and the like. The thicknesses of the pellets 5100 are preferably uniform; the reason for this is described later. In addition, the sputtered particle preferably has a pellet shape with a small thickness as compared to a dice shape with a large thickness. For example, the thickness of the pellet 5100 is greater than or equal to 0.4 nm and less than or equal to 1 nm, preferably greater than or equal to 0.6 nm and less than or equal to 0.8 nm. In addition, for example, the width of the pellet 5100 is greater than or equal to 1 nm and less than or equal to 3 nm, preferably greater than or equal to 1.2 nm and less than or equal to 2.5 nm. The pellet 5100 corresponds to the initial nucleus in the description of (1) in FIG. 12. For example, in the case where the ion 5101 collides with the target 5130 including an In—Ga—Zn oxide, the pellet 5100 that includes three layers of a Ga—Zn—O layer, an In—O layer, and a Ga—Zn—O layer as shown in FIG. 14B is ejected. Note that FIG. 14C shows the structure of the pellet 5100 observed from a direction parallel to the c-axis. Therefore, the pellet 5100 has a nanometer-sized sandwich structure including two Ga—Zn—O layers (pieces of bread) and an In—O layer (filling).

The pellet 5100 may receive a charge when passing through the plasma, so that side surfaces thereof are negatively or positively charged. The pellet 5100 includes an oxygen atom on its side surface, and the oxygen atom may be negatively charged. In this manner, when the side surfaces are charged with the same polarity, charges repel each other, and accordingly, the pellet 5100 can maintain a flat-plate shape. In the case where a CAAC-OS is an In—Ga—Zn oxide, there is a possibility that an oxygen atom bonded to an indium atom is negatively charged. There is another possibility that an oxygen atom bonded to an indium atom, a gallium atom, or a zinc atom is negatively charged. In addition, the pellet 5100 may grow by being bonded with an indium atom, a gallium atom, a zinc atom, an oxygen atom, or the like when passing through plasma. A difference in size between (2) and (1) in FIG. 12 corresponds to the amount of growth in plasma. Here, in the case where the temperature of the substrate 5120 is at around room temperature, the pellet 5100 does not grow anymore; thus, an nc-OS is formed (see FIG. 13B). An nc-OS can be deposited when the substrate 5120 has a large size because a temperature at which the deposition of an nc-OS is carried out is approximately room temperature. Note that in order that the pellet 5100 grows in plasma, it is effective to increase deposition power in sputtering. High deposition power can stabilize the structure of the pellet 5100.

As shown in FIGS. 38A and 38B, the pellet 5100 flies like a kite in plasma and flutters up to the substrate 5120. Since the pellets 5100 are charged, when the pellet 5100 gets close to a region where another pellet 5100 has already been deposited, repulsion is generated. Here, above the substrate 5120, a magnetic field in a direction parallel to the top surface of the substrate 5120 (also referred to as a horizontal magnetic field) is generated. A potential difference is given between the substrate 5120 and the target 5130, and accordingly, current flows from the substrate 5120 toward the target 5130. Thus, the pellet 5100 is given a force (Lorentz force) on the top surface of the substrate 5120 by an effect of the magnetic field and the current. This is explainable with Fleming's left-hand rule.

The mass of the pellet 5100 is larger than that of an atom. Therefore, to move the pellet 5100 over the top surface of the substrate 5120, it is important to apply some force to the pellet 5100 from the outside. One kind of the force may be force which is generated by the action of a magnetic field and current. In order to increase a force applied to the pellet 5100, it is preferable to provide, on the top surface, a region where the magnetic field in a direction parallel to the top surface of the substrate 5120 is 10 G or higher, preferably 20 G or higher, further preferably 30 G or higher, still further preferably 50 G or higher. Alternatively, it is preferable to provide, on the top surface, a region where the magnetic field in a direction parallel to the top surface of the substrate 5120 is 1.5 times or higher, preferably twice or higher, further preferably 3 times or higher, still further preferably 5 times or higher as high as the magnetic field in a direction perpendicular to the top surface of the substrate 5120.

At this time, the magnets and the substrate 5120 are moved or rotated relatively, whereby the direction of the horizontal magnetic field on the top surface of the substrate 5120 continues to change. Therefore, the pellet 5100 can be moved in various directions on the top surface of the substrate 5120 by receiving forces in various directions.

Furthermore, as shown in FIG. 38A, when the substrate 5120 is heated, resistance between the pellet 5100 and the substrate 5120 due to friction or the like is low. As a result, the pellet 5100 glides above the top surface of the substrate 5120. The glide of the pellet 5100 is caused in a state where its flat plane faces the substrate 5120. Then, when the pellet 5100 reaches the side surface of another pellet 5100 that has been already deposited, the side surfaces of the pellets 5100 are bonded. At this time, the oxygen atom on the side surface of the pellet 5100 is released. With the released oxygen atom, oxygen vacancies in a CAAC-OS might be filled; thus, the CAAC-OS has a low density of defect states. Note that the temperature of the top surface of the substrate 5120 is, for example, higher than or equal to 100° C. and lower than 500° C., higher than or equal to 150° C. and lower than 450° C., or higher than or equal to 170° C. and lower than 400° C. Hence, even when the substrate 5120 has a large size, it is possible to deposit a CAAC-OS.

Furthermore, the pellet 5100 is heated on the substrate 5120, whereby atoms are rearranged, and the structure distortion caused by the collision of the ion 5101 can be reduced. The pellet 5100 whose structure distortion is reduced is substantially single crystal. Even when the pellets 5100 are heated after being bonded, expansion and contraction of the pellet 5100 itself hardly occur, which is caused by turning the pellet 5100 into substantially single crystal. Thus, formation of defects such as a grain boundary due to expansion of a space between the pellets 5100 can be prevented, and accordingly, generation of crevasses can be prevented.

The CAAC-OS does not have a structure like a board of a single crystal oxide semiconductor but has arrangement with a group of pellets 5100 (nanocrystals) like stacked bricks or blocks. Furthermore, a grain boundary does not exist therebetween. Therefore, even when deformation such as shrink occurs in the CAAC-OS owing to heating during deposition, heating or bending after deposition, it is possible to relieve local stress or release distortion. Therefore, this structure is suitable for a flexible semiconductor device. Note that the nc-OS has arrangement in which pellets 5100 (nanocrystals) are randomly stacked.

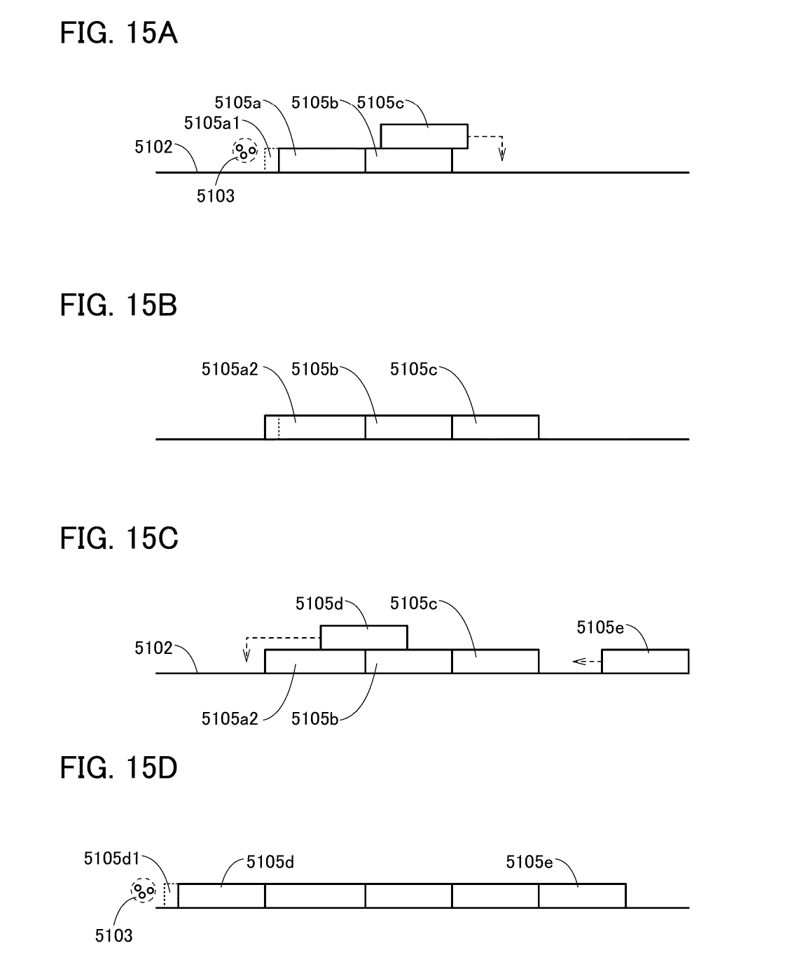

When the target is sputtered with an ion, in addition to the pellets, zinc oxide or the like may be ejected. The zinc oxide is lighter than the pellet and thus reaches the top surface of the substrate 5120 before the pellet. As a result, the zinc oxide forms a zinc oxide layer 5102 with a thickness greater than or equal to 0.1 nm and less than or equal to 10 nm, greater than or equal to 0.2 nm and less than or equal to 5 nm, or greater than or equal to 0.5 nm and less than or equal to 2 nm. FIGS. 15A to 15D are cross-sectional schematic views.

As illustrated in FIG. 15A, a pellet 5105a and a pellet 5105b are deposited over the zinc oxide layer 5102. Here, side surfaces of the pellet 5105a and the pellet 5105b are in contact with each other. In addition, a pellet 5105c is deposited over the pellet 5105b, and then glides over the pellet 5105b. Furthermore, a plurality of particles 5103 ejected from the target together with the zinc oxide is crystallized by heating of the substrate 5120 to form a region 5105a1 on another side surface of the pellet 5105a. Note that the plurality of particles 5103 may contain oxygen, zinc, indium, gallium, or the like.

Then, as illustrated in FIG. 15B, the region 5105a1 grows to part of the pellet 5105a to form a pellet 5105a2. In addition, a side surface of the pellet 5105c is in contact with another side surface of the pellet 5105b.

Next, as illustrated in FIG. 15C, a pellet 5105d is deposited over the pellet 5105a2 and the pellet 5105b, and then glides over the pellet 5105a2 and the pellet 5105b. Furthermore, a pellet 5105e glides toward another side surface of the pellet 5105c over the zinc oxide layer 5102.

Then, as illustrated in FIG. 15D, the pellet 5105d is placed so that a side surface of the pellet 5105d is in contact with a side surface of the pellet 5105a2. Furthermore, a side surface of the pellet 5105e is in contact with another side surface of the pellet 5105c. A plurality of particles 5103 ejected from the target together with the zinc oxide is crystallized by heating of the substrate 5120 to form a region 5105d1 on another side surface of the pellet 5105d.

As described above, deposited pellets are placed to be in contact with each other and then growth is caused at side surfaces of the pellets, whereby a CAAC-OS is formed over the substrate 5120. Therefore, each pellet of the CAAC-OS is larger than that of the nc-OS. A difference in size between (3) and (2) in FIG. 12 corresponds to the amount of growth after deposition.

When spaces between pellets 5100 are extremely small, the pellets may form a large pellet. The large pellet has a single crystal structure. For example, the size of the large pellet may be greater than or equal to 10 nm and less than or equal to 200 nm, greater than or equal to 15 nm and less than or equal to 100 nm, or greater than or equal to 20 nm and less than or equal to 50 nm, when seen from the above. Therefore, when a channel formation region of a transistor is smaller than the large pellet, the region having a single crystal structure can be used as the channel formation region. Furthermore, when the size of the pellet is increased, the region having a single crystal structure can be used as the channel formation region, the source region, and the drain region of the transistor.

In this manner, when the channel formation region or the like of the transistor is formed in a region having a single crystal structure, the frequency characteristics of the transistor can be increased in some cases.

As shown in such a model, the pellets 5100 are considered to be deposited on the substrate 5120. Thus, a CAAC-OS can be deposited even when a formation surface does not have a crystal structure, which is different from film deposition by epitaxial growth. For example, even when the top surface (formation surface) of the substrate 5120 has an amorphous structure (e.g., the top surface is formed of amorphous silicon oxide), a CAAC-OS can be formed.

In addition, it is found that in formation of the CAAC-OS, the pellets 5100 are arranged in accordance with the top surface shape of the substrate 5120 that is the formation surface even when the formation surface has unevenness. For example, in the case where the top surface of the substrate 5120 is flat at the atomic level, the pellets 5100 are arranged so that flat planes parallel to the a-b plane face downwards. In the case where the thicknesses of the pellets 5100 are uniform, a layer with a uniform thickness, flatness, and high crystallinity is formed. By stacking n layers (n is a natural number), the CAAC-OS can be obtained.

In the case where the top surface of the substrate 5120 has unevenness, a CAAC-OS in which n layers (n is a natural number) in each of which the pellets 5100 are arranged along the unevenness are stacked is formed. Since the substrate 5120 has unevenness, a gap is easily generated between the pellets 5100 in the CAAC-OS in some cases. Note that owing to intermolecular force, the pellets 5100 are arranged so that a gap between the pellets is as small as possible even on the unevenness surface. Therefore, even when the formation surface has unevenness, a CAAC-OS with high crystallinity can be obtained.

As a result, laser crystallization is not needed for formation of a CAAC-OS, and a uniform film can be formed even over a large-sized glass substrate or the like.

Since a CAAC-OS is deposited in accordance with such a model, the sputtered particle preferably has a pellet shape with a small thickness. Note that when the sputtered particles have a dice shape with a large thickness, planes facing the substrate 5120 vary; thus, the thicknesses and orientations of the crystals cannot be uniform in some cases.

According to the deposition model described above, a CAAC-OS with high crystallinity can be formed even on a formation surface with an amorphous structure.

### Embodiment 5

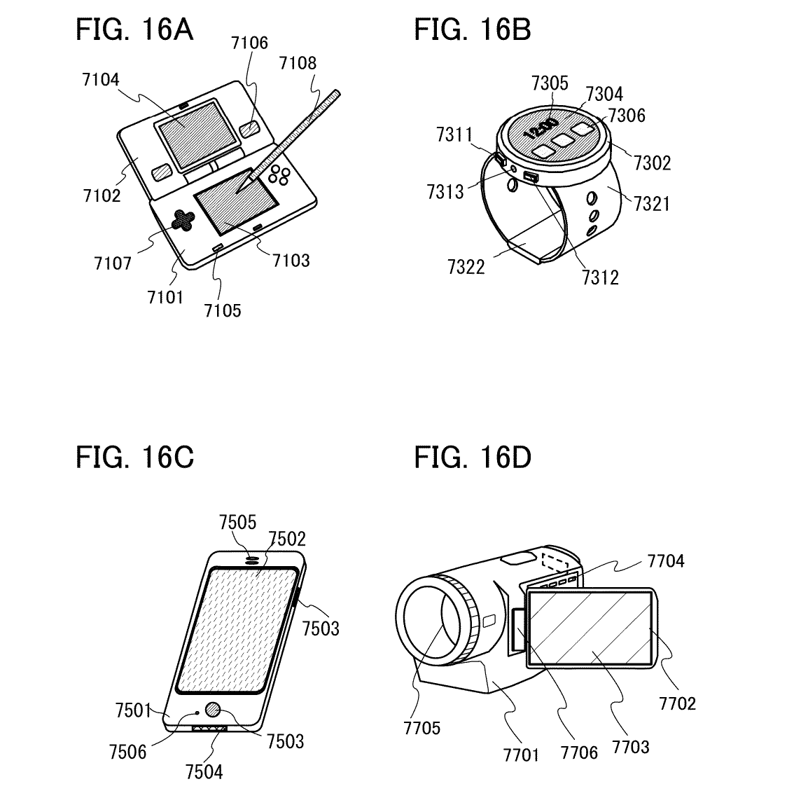

In this embodiment, examples of an electronic device to which the display device of one embodiment of the present invention can be applied will be described with reference to FIGS. 16A to 16D.

Examples of an electronic device including the display device include television sets (also referred to as televisions or television receivers), monitors of computers or the like, cameras such as digital cameras or digital video cameras, digital photo frames, mobile phones (also referred to as cellular phones or mobile phone devices), portable game machines, portable information terminals, audio reproducing devices, and large game machines such as pachinko machines. Specific examples of these electronic devices are illustrated in FIGS. 16A to 16D.

FIG. 16A illustrates a portable game machine including a housing 7101, a housing 7102, a display portion 7103, a display portion 7104, a microphone 7105, speakers 7106, an operation key 7107, a stylus 7108, and the like. The display device according to one embodiment of the present invention can be used for the display portion 7103 or the display portion 7104. When the display device according to one embodiment of the present invention is used as the display portion 7103 or 7104, it is possible to provide a user-friendly portable game machine with quality that hardly deteriorates. Although the portable game machine illustrated in FIG. 16A includes two display portions, the display portion 7103 and the display portion 7104, the number of display portions included in the portable game machine is not limited to two.

FIG. 16B illustrates a smart watch, which includes a housing 7302, a display portion 7304, operation buttons 7311 and 7312, a connection terminal 7313, a band 7321, a clasp 7322, and the like. The display device according to one embodiment of the present invention can be used for the display portion 7304.

FIG. 16C illustrates a portable information terminal, which includes a display portion 7502 incorporated in a housing 7501, operation buttons 7503, an external connection port 7504, a speaker 7505, a microphone 7506, and the like. The display device of one embodiment of the present invention can be used for the display portion 7502.

FIG. 16D illustrates a video camera, which includes a first housing 7701, a second housing 7702, a display portion 7703, operation keys 7704, a lens 7705, a joint 7706, and the like. The operation keys 7704 and the lens 7705 are provided for the first housing 7701, and the display portion 7703 is provided for the second housing 7702. The first housing 7701 and the second housing 7702 are connected to each other with the joint 7706, and the angle between the first housing 7701 and the second housing 7702 can be changed with the joint 7706. Images displayed on the display portion 7703 may be switched in accordance with the angle at the joint 7706 between the first housing 7701 and the second housing 7702. The display device according to one embodiment of the present invention can be used for the image display portion 7703.

This embodiment can be combined with any of the other embodiments in this specification as appropriate.

### EXPLANATION OF REFERENCE

100: display panel, 101: substrate, 102: element region, 103: display element, 105: adhesive layer, 107: display element, 109: substrate, 110: display region, 113: element layer, 117: element layer, 120: transistor, 121: transistor layer, 122: insulating film, 123: insulating film, 125: planarization insulating film, 126: conductive film, 127: planarization insulating film, 131: lower electrode, 131B: lower electrode, 131G: lower electrode, 131R: lower electrode, 133: EL layer, 135: upper electrode, 141: insulating film, 142: spacer, 143: insulating film, 145: capacitor, 146: transistor, 160: transistor, 171: electrode layer, 173: polymer-dispersed liquid crystal layer, 174: light-transmitting state, 175: electrode layer, 180: transistor, 181: coloring layer, 183: light-blocking layer, 186: connection electrode, 187: conductive film, 188: anisotropic conductive film, 189: touch sensor, 190: insulating film, 191: transistor layer, 192: insulating film, 193: light-blocking film, 194: conductive film, 195: conductive film, 196: conductive film, 197: planarization insulating film, 198: planarization insulating film, 199: planarization insulating film, 200: display device, 203: driving device, 205: light sensor, 409a: FPC, 409b: FPC, 500P: display panel, 500TP: input/output device, 502: pixel, 509: FPC, 510: base, 511: light-blocking layer, 610: base, 700: sensor panel, 710: base, 711: insulating film, 770: protective layer, 830: light-emitting element, 5100: pellet, 5100a: pellet, 5100b: pellet, 5101: ion, 5102: zinc oxide layer, 5103: particle, 5105a: pellet, 5105a1: region, 5105a2: pellet, 5105b: pellet, 5105c: pellet, 5105d: pellet, 5105d1: region, 5105e: pellet, 5120: substrate, 5130: target, 5161: region, 7101: housing, 7102: housing, 7103: display portion, 7104: display portion, 7105: microphone, 7106: speaker, 7107: operation key, 7108: stylus, 7302: housing, 7304: display portion, 7311: operation button, 7312: operation button, 7313: connection terminal, 7321: band, 7322: clasp, 7501: housing, 7502: display portion, 7503: operation button, 7504: external connection port, 7505: speaker, 7506: microphone, 7701: housing, 7702: housing, 7703: display portion, 7704: operation key, 7705: lens, 7706: connection portion.

This application is based on Japanese Patent Application serial no. 2014-162359 filed with Japan Patent Office on Aug. 8, 2014, the entire contents of which are hereby incorporated by reference.

1. A display device comprising:
a first display element; and
a second display element,
wherein the first display element is capable of emitting light,
wherein the second display element has a first state which is capable of transmitting light or a second state which is capable of dispersing light, and
wherein the second display element is overlapped with the first display element on a light-emitting side of the first display element.

2. The display device according to claim 1, further comprising a driving device,
wherein a first image signal is supplied from the driving device to the first display element in the case where an illuminance under which the display device is used is less than a predetermined illuminance, and
wherein a second image signal is supplied from the driving device to the second display element in the case where the illuminance under which the display device is used is more than or equal to the predetermined illuminance.

3. The display device according to claim 1, further comprising a coloring layer,
wherein the second display element is between the coloring layer and the first display element.

4. The display device according to claim 1,
wherein the first display element comprises a layer containing a light-emitting organic compound, and
wherein the second display element comprises a layer containing a polymer-dispersed liquid crystal.

5. The display device according to claim 1, further comprising:
a first transistor electrically connected to the first display element; and
a second transistor electrically connected to the second display element,
wherein each of the first transistor and the second transistor comprises an oxide semiconductor layer comprising indium, gallium, and zinc.

6. The display device according to claim 1, wherein the first display element and the second display element are bonded to each other by an adhesive layer.

7. A display device comprising:
a plurality of first display elements; and
a plurality of second display elements,
wherein the plurality of first display elements is capable of emitting light,
wherein each of the plurality of second display elements separately has a first state which is capable of transmitting light or a second state which is capable of dispersing light,
wherein one of the plurality of second display elements is overlapped with one of the plurality of first display elements on a light-emitting side of the one of the plurality of first display elements, and
wherein each of the plurality of first display elements and the plurality of second display elements is arranged in a matrix in a display region.

8. The display device according to claim 7, further comprising a driving device,
wherein a first image signal is supplied from the driving device to the one of the plurality of first display elements in the case where an illuminance under which the display device is used is less than a predetermined illuminance, and
wherein a second image signal is supplied from the driving device to the one of the plurality of second display elements in the case where the illuminance under which the display device is used is more than or equal to the predetermined illuminance.

9. The display device according to claim 7, further comprising a coloring layer,
wherein the one of the plurality of second display elements is between the coloring layer and the one of the plurality of first display elements.

10. The display device according to claim 7,
wherein the one of the plurality of first display elements comprises a layer containing a light-emitting organic compound, and
wherein the one of the plurality of second display elements comprises a layer containing a polymer-dispersed liquid crystal.

11. The display device according to claim 7, further comprising:
a first transistor electrically connected to the one of the plurality of first display elements; and
a second transistor electrically connected to the one of the plurality of second display elements,
wherein each of the first transistor and the second transistor comprises an oxide semiconductor layer comprising indium, gallium, and zinc.

12. The display device according to claim 7, wherein the plurality of first display elements and the plurality of second display elements are bonded to each other by an adhesive layer.

13. A display device comprising:
a light sensor;
a driving device;
a first display element; and
a second display element,
wherein the first display element is capable of emitting light,
wherein the light sensor is capable of sensing an illuminance of an use environment of the display device,
wherein the driving device is capable of supplying a first image signal to the first display element and a signal to the second display element to transmit light in the case where the illuminance sensed by the light sensor is less than a predetermined illuminance,
wherein the driving device is capable of supplying a second image signal to the second display element in the case where the illuminance sensed by the light sensor is more than or equal to the predetermined illuminance,
wherein the second display element has a first state which is capable of transmitting light or a second state which is capable of dispersing light, and
wherein the second display element is overlapped with the first display element on a light-emitting side of the first display element.

14. The display device according to claim 13, further comprising a coloring layer,
wherein the second display element is between the coloring layer and the first display element.

15. The display device according to claim 13,
wherein the first display element comprises a layer containing a light-emitting organic compound, and
wherein the second display element comprises a layer containing a polymer-dispersed liquid crystal.

16. The display device according to claim 13, further comprising:
a first transistor electrically connected to the first display element; and
a second transistor electrically connected to the second display element,
wherein each of the first transistor and the second transistor comprises an oxide semiconductor layer comprising indium, gallium, and zinc.

17. The display device according to claim 13, wherein the first display element and the second display element are bonded to each other by an adhesive layer.

18. A driving method of a display device, comprising:
a first step of obtaining an illuminance data;
a second step of supplying a first image signal to a first display element and a signal to a second display element to transmit light; and
a third step of turning the first display element off and supplying a second image signal to the second display element,
wherein, in the case where the illuminance data contains data of illuminance less than a predetermined illuminance in the first step, the second step starts after performing the first step, and
wherein, in the case where the illuminance data contains data of illuminance more than or equal to the predetermined illuminance in the first step, the third step starts after performing the first step.

19. The driving method according to claim 18,
wherein the second display element has a first state which is capable of transmitting light or a second state which is capable of dispersing light, and
wherein the second display element is overlapped with the first display element on a light-emitting side of the first display element.

20. The driving method according to claim 18,
wherein the first display element comprises a layer containing a light-emitting organic compound, and
wherein the second display element comprises a layer containing a polymer-dispersed liquid crystal.
